(19) United States
(12) Patent Application Publication
(10) Pub. No.: US 2025/0113641 A1
(43) Pub. Date: Apr. 3, 2025

(54) STACKED QUANTUM DOT SENSORS AND METHODS OF FORMING THE SAME

(71) Applicant: Adeia Semiconductor Bonding Technologies Inc., San Jose, CA (US)

(72) Inventors: Rajesh Katkar, Milpitas, CA (US); Belgacem Haba, Saratoga, CA (US); Cyprian Emeka Uzoh, San Jose, CA (US); Oliver Zhao, Daly City, CA (US)

(21) Appl. No.: 18/896,467

(22) Filed: Sep. 25, 2024

Related U.S. Application Data
(60) Provisional application No. 63/541,578, filed on Sep. 29, 2023.

(51) Int. Cl. H10F 39/00; H10F 39/95; H10F 71/00; H10F 77/20

(52) U.S. Cl. CPC H10F 39/811; H10F 39/024; H10F 39/8067; H10F 39/95; H10F 71/138; H10F 77/244

(57) ABSTRACT

A method of forming a stacked image sensor comprises providing a first substrate and a second substrate. The first substrate comprises a first matrix comprising first quantum dots, a first dielectric layer adjacent to the first matrix, and first bond pads disposed in the first dielectric layer. The second substrate comprises a second matrix comprising second quantum dots, a second dielectric layer adjacent to the second matrix, and second bond pads disposed in the second dielectric layer. The method includes hybrid bonding the first substrate to the second substrate without use of an intervening adhesive to form the stacked image sensor, where the hybrid bonding connects the first bond pads to the second bond pads.

### CROSS-REFERENCE TO RELATED APPLICATION

This application claims the benefit of U.S. Provisional Patent Application No. 63/541,578, filed Sep. 29, 2023, which is hereby incorporated by reference herein in its entirety.

### FIELD

The present disclosure relates to sensors formed using quantum dots, herein “quantum dot sensors,” and devices including quantum dot sensors, herein “quantum dot sensor devices,” and in particular, high efficiency quantum dot image sensor devices methods of manufacturing the same.

### BACKGROUND

Since different quantum dots (e.g., material and/or size) may not be compatible to form a homogeneous solution, it may be a challenging process to form a sensor using quantum dots. Methods of manufacturing quantum dot sensors (e.g. quantum dot image sensors) that are not burdened by process compatibility of different types of quantum dots is required.

### SUMMARY

Embodiments herein provide for methods of forming stacked quantum dot sensors by separately processing different quantum dots into different films (e.g., layers or substrates) and bonding the separate films (e.g., layers or substrates) together. Advantageously, the stacked quantum dot sensors may enable the processing of different quantum dots without being burdened with process compatibility of the different quantum dots. Each film may comprise a quantum dot sensor comprising quantum dots or a matrix comprising quantum dots disposed in a material layer (e.g., transparent material, optically transparent material, non-conductive material, transparent non-conductive material, etc.). Each film may comprise a quantum dot sensor that improves collection of photogenerated carrier using a conductive matrix, a semiconductive matrix, a matrix comprising conductive particles and quantum dots in a transparent non-conductive material, conductive structures, and/or porous conductive structures. A conductive matrix may comprise quantum dots in a transparent conductive material or quantum dots and conductive particles in a transparent conductive material. Advantageously, the conductive matrix, the semiconductive matrix, the matrix comprising conductive particles and quantum dots in a non-conductive material, conductive structures, and/or the porous conductive structures may help enable a photogenerated carrier to be transported to an electrode to improve efficiency of the quantum dot sensor. The embodiments may enable quantum dot sensors with reduced density of quantum dots, saving on material costs, and reducing the density of quantum dots may enable quantum dot sensors with increased thickness to enable more capturing of light over conventional sensors using quantum dots.

One general aspect includes a method of forming a stacked sensor. The method may include providing a first substrate and providing a second substrate. The first substrate may include a first matrix including first quantum dots, a first dielectric layer adjacent to the first matrix, and first bond pads disposed in the first dielectric layer. The second substrate may include a second matrix including second quantum dots, a second dielectric layer adjacent to the second matrix, and second bond pads disposed in the second dielectric layer. The method may further include hybrid bonding the first substrate to the second substrate without use of an intervening adhesive to form the stacked image sensor, where the hybrid bonding connects the first bond pads to the second bond pads.

In some embodiments, the first matrix comprises a first conductive matrix including the first quantum dots disposed in a first transparent conductive material. The second matrix may comprise a second conductive matrix including the second quantum dots disposed in a second transparent conductive material.

In some embodiments, the method includes, subsequent to hybrid bonding the first substrate and the second substrate, forming pixel stacks of the stacked image sensor by removing portions of the first matrix and portions of the second matrix.

In some embodiments, providing the first substrate comprises patterning first electrodes, where the first matrix is in electrical communication to the first electrodes. Providing the second substrate may comprise patterning second electrodes, where the second matrix is in electrical communication with the second electrodes. The first electrodes may comprise a rectangular array of first electrodes, interdigitated first electrodes, or alternating concentric rings of first electrodes when viewed from top down or bottom up. The second electrodes may comprise a rectangular array of second electrodes, interdigitated second electrodes, or alternating concentric rings of second electrodes when viewed from top down or bottom up.

In some embodiments, providing the first substrate comprises patterning the first matrix. Providing the second substrate may comprise patterning the second matrix. The method may include, prior to hybrid bonding, aligning the first substrate and the second substrate to offset the patterned first matrix and the patterned second matrix when viewed from top down or bottom up.

In some embodiments, providing the first substrate comprises, prior to forming the first matrix, forming a first reflective layer, where the first reflective layer is shaped to direct incident light towards the first matrix of the first substrate. Providing the second substrate may comprise, prior to forming the second matrix, forming a second reflective layer, where the second reflective layer is shaped to direct incident light toward the second matrix of the second substrate.

In some embodiments, providing the first substrate comprises, forming the first matrix on a bottom first electrode of the first electrodes; and forming a top first electrode of the first electrodes on the first matrix, where the top first electrode comprises a transparent conductive oxide. The transparent conductive oxide may comprise indium tin oxide, zinc oxide, tin oxide, aluminum doped zinc oxide, indium oxide, cadmium oxide, or some combination thereof.

In some embodiments, providing the first substrate comprises, prior or subsequent to forming the first matrix, forming a third dielectric layer and the third bond pads disposed in the third dielectric layer. The image processor device may include fourth bond pads disposed in a fourth dielectric layer. The method may include hybrid bonding the stacked image sensor to an image processor device without use of an intervening adhesive to connect third bond pads to fourth bond pads. The stacked image sensor device may be hybrid bonded to an image processor device without use of an intervening adhesive to connect third bond pads to fourth bond pads.

Another general aspect includes a stacked image sensor. The stacked image sensor includes a first substrate and a second substrate. The first substrate includes a first matrix comprising first quantum dots, a first dielectric layer adjacent to the first matrix, and first bond pads disposed in the first dielectric layer. The second substrate includes a second matrix comprising second quantum dots, a second dielectric layer adjacent to the second matrix, and second bond pads disposed in the second dielectric layer. The first substrate is hybrid bonded to the second substrate without use of an intervening adhesive to form the stacked image sensor to connect the first bond pads to the second bond pads.

In some embodiments, the first matrix comprises a first conductive matrix including the first quantum dots disposed in a first transparent conductive material. The second matrix may comprise a second conductive matrix including the second quantum dots disposed in a second transparent conductive material.

In some embodiments, the stacked image sensor comprises a repeating pattern of first matrices and corresponding first electrodes, and a repeating pattern of second matrices and corresponding second electrodes.

In some embodiments, the stacked image sensor includes first electrodes of the first substrate, where the first matrix is in electrical communication to the first electrodes. The stacked image sensor may include second electrodes of the second substrate, where the second matrix is in electrical communication with the second electrodes. The first electrodes may comprise a rectangular array of first electrodes, interdigitated first electrodes, or alternating concentric rings of first electrodes when viewed from top down or bottom up. The second electrodes may comprise a rectangular array of second electrodes, interdigitated second electrodes, or alternating concentric rings of second electrodes when viewed from top down or bottom up.

In some embodiments, the stacked image sensor may include a third dielectric layer of the first substrate, where portions of the third dielectric is laterally adjacent to a patterned first matrix, and a fourth dielectric layer of the second substrate, where portions of the fourth dielectric layer is laterally adjacent to a patterned second matrix. The patterned first matrix may be offset from the patterned second matrix when viewed from top down or bottom up.

In some embodiments, the stacked image sensor may include a first reflective layer of the first substrate. The first reflective layer may be shaped to direct incident light towards the first matrix of the first substrate. The stacked image sensor may include a second reflective layer of the second substrate. The second reflective layer may be shaped to direct incident light toward the second matrix of the second substrate.

In some embodiments, the stacked image sensor may include a bottom first electrode, where the first matrix is formed on the bottom first electrode, and a top first electrode on the first matrix, where the top first electrode comprises a transparent conductive oxide. The transparent conductive oxide may comprise indium tin oxide, zinc oxide, tin oxide, aluminum doped zinc oxide, indium oxide, cadmium oxide, or some combination thereof.

Another general aspect includes a stacked image sensor device. The stacked image sensor device includes the stacked image sensor hybrid bonded to an image processor device without use of an intervening adhesive. The first substrate further comprises a third dielectric layer and third bond pads disposed in the third dielectric layer, and the image processor device comprises fourth bond pads disposed in a fourth dielectric layer. The third bond pads are connected to the fourth bond pads without use of an intervening adhesive.

### BRIEF DESCRIPTION OF THE DRAWINGS

The above and other objects and advantages of the disclosure will be apparent upon consideration of the following detailed description, taken in conjunction with the accompanying drawings.

FIGS. 1A-1B schematically illustrates example methods of forming stacked sensors, in accordance with embodiments of the present disclosure;

FIGS. 2A-2D schematically illustrates example sensors, in accordance with embodiments of the present disclosure;

FIG. 3A schematically illustrates example configurations of electrodes, in accordance with embodiments of the present disclosure;

FIG. 3B is an illustrative schematic sectional side view of a stacked sensor, in accordance with embodiments of the present disclosure;

FIG. 3C is an illustrative schematic sectional side view of quantum dots deposited in an opening of a substrate configured to enhance light collection, in accordance with embodiments of the present disclosure;

FIGS. 4A-4B schematically illustrates hybrid bonding methods for forming an image sensor devices, in accordance with embodiments of the present disclosure; and

FIG. 5 is an illustrative schematic sectional side view of an image sensor with conductive particles, in accordance with embodiments of the present disclosure;

FIG. 6 is an illustrative schematic sectional side view of an image sensor with conductive nano structures, in accordance with embodiments of the present disclosure;

FIG. 7 is an illustrative schematic sectional side view of an image sensor with porous conductive structures, in accordance with embodiments of the present disclosure; and

FIGS. 8A-8B schematically illustrates a hybrid bonding method, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein provide for methods of forming sensors (e.g., stacked sensors, quantum dot sensors, high efficiency sensors, image sensors, optical sensors, shortwave infrared sensors) by separately processing different quantum dots into different films (e.g., layers or substrates) and bonding the separate films (e.g., layers or substrates) together. Separately processing different quantum dots enables quantum dots of same or similar materials, shapes, and/or sizes to be processed as homogeneous solutions of quantum dots. Each film may comprise a quantum dot sensor comprising quantum dots (e.g., quantum dot layer, matrix comprising quantum dots disposed in a material layer, quantum dots disposed in a transparent material, optically transparent material, transparent non-conductive material, or transparent conductive material, etc.). Each film may comprise a high efficiency sensor (e.g., photodiode, light detector, or an image sensor comprising a plurality of sensors) using quantum dots. A high efficiency sensor enables collection of photogenerated carriers via a conductive matrix, conductive particles, conductive structures, and/or porous conductive structures, reducing or eliminating the need for a photogenerated carrier on a quantum dot to hop to adjacent quantum dots to reach an electrode.

A quantum dot sensor, such as a photodiode and/or other light detector formed using quantum dots may include electrodes, one or more quantum dot layers, and an encapsulant layer. An image sensor may comprise a plurality of sensors (e.g., sensor pixels, photo sites). An image sensor device may include an image sensor coupled to read-out integrated circuits (ROICs) or an image processor device. Each quantum dot layer may be tuned to absorb light in a desired range of wavelengths by using quantum dots formed of different materials and/or having different sizes. For example, quantum dot materials (e.g., PbS, CdS, CdSe, ZiSe) may have a tunable absorption spectrum to provide image sensing across a range of wavelengths. The material of the quantum dot and the size of the particles can be adjusted to absorb any wavelength of light (e.g. visible and infrared spectrum). Different materials and particle sizes could be further mixed to adjust to wider band of wavelengths. Quantum dot material may be applied by inkjet printing or spin coating from a colloidal solution.

A quantum dot layer may comprise quantum dots in a transparent insulating material (e.g., polymer, encapsulant). Quantum dots may be used to detect light in IR, NIR, SWIR, visible, or any suitable wavelength range. Each quantum dot layer may be tuned to absorb light in a desired range of wavelengths by using quantum dots formed of different materials and/or having different sizes. For example, different quantum dots may be used to detect light in a range of infrared (IR) wavelengths (e.g., short wave infrared (SWIR), near IR (NIR) wavelengths) or in different ranges of visible wavelengths (e.g., red, green, and blue wavelengths). Different quantum dots (e.g., material, shape, and/or size) may not be compatible to form a homogeneous solution, and it may be a challenging process to form a sensor using quantum dots.

When a quantum dot in a sensor pixel absorbs a photon, an electron or photogenerated carrier escapes its localized bond. The edge of the quantum dot confines the transport of the electron, but the electron may hop to a neighboring quantum dot if close enough. The electron performs sequential hops between quantum dots until it reaches an electrode of the sensor pixel to be counted by the pixel's readout circuit. A quantum dot layer may be thin to enable a limited number of electron hops before getting counted. However, quantum dot can have defects or imperfections in their crystal lattices because of because of their small size and large surface area. A defective quantum dot along a path for a photogenerated carrier to get to an electrode may cause the photogenerated carriers to recombine before the electron can reach an electrode. A photon absorbed by a quantum dot that generates an electron that recombines on a defective quantum dot is therefore not detected by the pixel circuitry, reducing the signal that reaches an image sensor processor. A few defective quantum dots can affect sensor performance by reducing the collected signal.

To help address the above problems, embodiments herein provide for a stacked sensor (e.g., stacked photodiode, detector, or an image sensor comprising a plurality of sensors) using quantum dots that enables the processing of different quantum dots without being burdened with process compatibility of the different quantum dots and improves collection of photogenerated carrier using a conductive matrix, a matrix comprising conductive particles and quantum dots in a transparent insulating material layer (e.g., non-conductive transparent material layer), a semiconductive matrix, conductive structures, and/or porous conductive structures. A conductive matrix may comprise quantum dots in a transparent conductive material layer or may comprise quantum dots and conductive particles in a transparent conductive material layer. In some embodiments, the transparent conductive material layer may comprise a transparent conductive oxide, a transparent conductive nitride, a doped dielectric layer or a layer such as 50 nm or less, 40 nm or less, 30 nm or less, 20 nm or less, 10 nm or less, 5 nm or less, 3 nm or less, or 2 nm or less of dielectric-metal dielectric laminate D₁MD₂, where D₁ and D₂ may comprise different dielectric layers, having different dielectric constants and different thicknesses. A conductive matrix, a matrix, a semiconductive matrix, conductive structures, and/or porous conductive structures help enable a photogenerated carrier to be transported to an electrode, reducing or eliminating the need for a photogenerated carrier to hop to adjacent quantum dots to reach an electrode of a photo site to be counted by the readout circuit of the photo site, improving performance of sensor with quantum dots over conventional sensors using quantum dots.

As described below, semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

As used herein, the term “quantum dot layer” and “matrix” may be used interchangeably. In some embodiments, the term “quantum dot layer” may refer to a layer of quantum dots. In some embodiments, the term “quantum dot layer” may refer to quantum dots disposed in a material layer. The material layer may comprise a conductive material, a semiconductive material, or a non-conductive material.

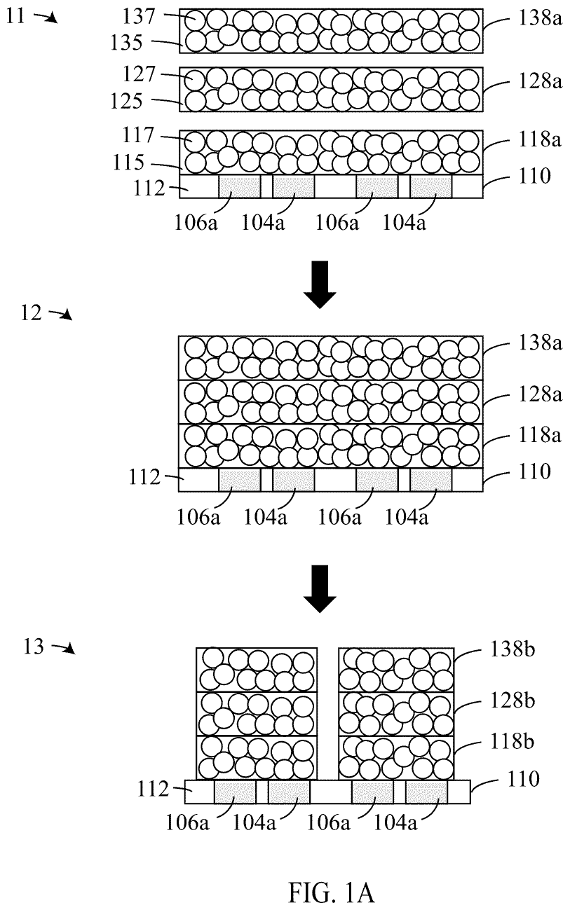

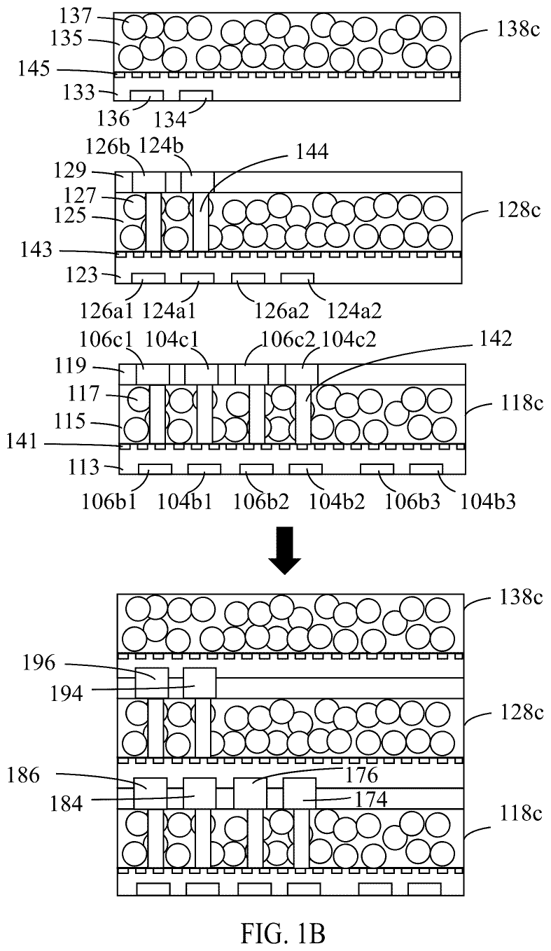

FIG. 1A is an illustrative schematic of sectional side views of forming an image sensor, in accordance with embodiments of the present disclosure. The image sensor is formed by stacking multiple quantum dot films (e.g., layers or substrates). The multiple quantum dot films may be bonded together to form stacked quantum dot films. The stacked quantum dot films may be patterned to form individual stacked pixel sensors for an image sensor. Although three quantum dot films are shown in FIG. 1A, any suitable number of quantum dot films may be used (e.g., 2 or more). In some embodiments, each quantum dot film of FIG. 1A shows a simplified quantum dot film, and a more detailed quantum dot film may include electrodes, one or more dielectric layers, an interconnect layer, interconnects in an insulating material, through vias in the insulating material, bond pads (e.g., conductive features), thin active semiconductor layer (e.g. amp select amplifiers, set/reset amplifiers, pixel select switches, analog to digital convertor (ADC), memory blocks, charge storage capacitors), or some combination thereof. An example of bonded, stacked, films including details such as electrodes, dielectric layers, through vias, and bond pads is shown in FIG. 1B.

At block 11, the method includes providing or forming three quantum dot films (e.g., layers or substrates). Each quantum dot film comprises quantum dots disposed in a respective material layer. In some embodiments, each quantum dot film may comprise quantum dots. In some embodiments, each quantum dot film may comprise a matrix comprising quantum dots. The matrix may comprise quantum dots disposed in any suitable material layer (e.g., transparent material, polymer, encapsulant, optically transparent material, conductive, non-conductive, dielectric, organic, inorganic, or semiconductive material layer). For example, a first quantum dot substrate 118a comprises first quantum dots 117 disposed in a first material layer 115. A second quantum dot substrate 128a comprises second quantum dots 127 disposed in a second material layer 125. A third quantum dot substrate 138a comprises third quantum dots 137 disposed in a third material layer 135. The quantum dots in each film may be different (e.g., different size, shape, density/distribution, and/or material), and the quantum dots in each film may be tuned to absorb a specific wavelength range. The material layer in each film may be any suitable material layer (e.g., optically transparent material, conductive, non-conductive, dielectric, organic, inorganic, or semiconductive material layer) and may comprise a same material or a different material than the material layers in the other films.

The quantum dots (e.g., first quantum dots 117, second quantum dots 127, and third quantum dots 137) in a respective quantum dot film (e.g., first quantum dot substrate 118a, second quantum dot substrate 128a, and third quantum dot substrate 138a) may be a different size, shape, and/or material from the quantum dots in the other quantum dot films. Quantum dots from each film may be tuned to absorb any suitable wavelength range (e.g., red, green, blue, infrared, near infrared (NIR), SWIR, or any suitable wavelength range). For example, the image sensor may be a visible image sensor, and quantum dots from each film may be tuned to absorb a specific wavelength range. The first quantum dots 117 may comprise green quantum dots or quantum dots that absorb green wavelengths (e.g., around 495-570 nm). The second quantum dots 127 may comprise blue quantum dots or quantum dots that absorb blue wavelengths (e.g., around 450-495 nm). The third quantum dots 137 may comprise red quantum dots or quantum dots that absorb red wavelengths (e.g., around 620-750 nm). For example, visible light incident on a surface of an image sensor (e.g., top surface of quantum dot substrate 138a) may comprise red, green, and blue wavelengths. The third quantum dots 137 may absorb red wavelengths, but are transparent to green wavelengths and blue wavelengths, and allow green and blue wavelengths to pass. The green and blue wavelengths may pass through the third quantum dot substrate 138a and reach the second quantum dot substrate 128a. The second quantum dots 127 may absorb blue wavelengths, but are transparent to green wavelengths, and allow green wavelengths to pass. The green wavelengths may pass through the second quantum dot substrate 218a and reach and be absorbed by the first quantum dots 117.

In some embodiments, the first quantum dots 117 are disposed on a substrate 110. The substrate 110 comprises a dielectric layer 112 and electrodes or bond pads (e.g., conductive features 104a and 106a) disposed in the dielectric layer 112. The dielectric layer 112 may comprise any suitable dielectric material such as those mentioned in the present disclosure (e.g., SiO₂, etc.). The conductive features 104a and 106a may comprise any suitable conductive material metal such as those mentioned in the present disclosure (e.g., metal, transparent conductive oxide, etc.). In some embodiments, the substrate 110 comprises an active semiconductor layer to capture and process the charge collected by quantum dot layer (e.g. pixel transistors, amp select amplifiers, set/reset amplifiers, pixel select switches, ADC, memory blocks, charge storage capacitors).

In some embodiments, the image sensor or a plurality of sensors may comprise a continuous quantum dot layer or matrix. For example, at least one quantum dot substrate 118a, 128a, and/or 138a comprises quantum dots, a quantum dot layer, or a matrix comprising quantum dots disposed in a first, second, and/or third material layer 115, 125, and 135 comprising a non-conductive or insulating material. The electrodes (e.g., electrodes 104a, 106a of FIG. 1A or electrodes 141, 143, and 145 of FIG. 1B) may comprise pairs of electrodes, and a spacing between a first pair of electrodes to a second pair of electrodes may be greater than about two times a thickness of a quantum dot layer or matrix. For example, minimal or no cross-talk may occur between sensor pixels if the pitch between pairs of electrodes is greater than two times the film thickness of a quantum dot layer or matrix. The distance between pairs of neighboring electrodes may be about a micron or 1 or more microns apart. The thickness of a quantum dot layer or matrix may be 10 nanometers, 10 or more nanometers, less than about 100 nanometers, or about 50-500 nanometers. Electrons generated by quantum dots in a quantum dot layer or matrix may be collected by the closest electrode pair, and would not be collected on an adjacent pair of electrodes more than a micron away.

In some embodiments, at least one quantum dot substrate 118a, 128a, and/or 138a comprises a conductive matrix. For example, the first, second, and/or third material layer 115, 125, and 135 may comprise a transparent conductive material (e.g., optically transparent conductive material).

The transparent conductive material layer may comprise a transparent conductive oxide and may partially encapsulate the quantum dots. The transparent conductive oxide may comprise indium tin oxide (ITO), zinc oxide (ZnO), tin oxide (SnO), aluminum doped zinc oxide (AZO), indium oxide (In₂O₃), cadmium oxide (CdO), or some combination thereof. The transparent conductive material layer may comprise a transparent conductive oxide or nitride, a doped dielectric layer, a layer of dielectric-metal dielectric laminate, or some combination thereof.

In some embodiments, a method of forming the first quantum dot substrate 118a comprises before or after forming the conductive matrix (e.g., quantum dot 117 in material layer 115), forming the electrodes (e.g., bond pads, conductive features 104a and 106a). For example, the electrodes may be formed before forming the conductive matrix, and the conductive matrix may be deposited on electrodes. In another example, the electrodes may be formed after forming the conductive matrix, and the electrodes may be deposited on the conductive matrix. The conductive matrix may be deposited on a substrate prior to electrode deposition, and the image sensor may be transferred to another substrate (e.g., temporary substrate) prior to bonding the electrodes (e.g., bond pads, conductive features 106a and 104a) to bond pads of an image processor device.

In some embodiments, forming the conductive matrix may comprise depositing, by physical vapor deposition, the transparent conductive material layer and depositing, by spin coating, the quantum dots. For example, the quantum dots may be deposited by spin coating a colloidal solution of quantum dots. In some embodiments, the quantum dots may be deposited using spray coating.

In some embodiments, forming the conductive matrix may comprise depositing, by physical vapor deposition, the transparent conductive material layer and depositing, by printing, the quantum dots. In some embodiments, For example, the quantum dots may be deposited using inkjet printing.

In some embodiments, forming the conductive matrix may comprise repeatedly and sequentially depositing quantum dot layers and transparent conductive material layers. For example, quantum dot layers may be deposited (e.g., by spin coating, spray coating, or inkjet printing), and transparent conductive material layers may be deposited (e.g., by physical vapor deposition).

In some embodiments, forming the conductive matrix may comprise depositing the transparent conductive material layer and the quantum dots from a suspension of quantum dots and transparent conductive material. The suspension may be deposited via spin coating, printing, or spray coating.

In some embodiments, the conductive matrix is patterned. The image sensor comprises a repeating pattern of conductive matrices and corresponding electrodes (shown as two patterned conductive matrices and pairs of electrodes). The conductive matrix may be patterned prior or subsequent to bonding the quantum dot substrates together.

In some embodiments, the conductive matrix may be formed patterned (e.g., printed). For example, using inkjet printing, a specific amount of quantum dot material (e.g. size, shape, volume, material type, etc.) may be directly deposited to pixel locations to form individual pixels. In some embodiments, a specific amount of a suspension of quantum dots material and transparent conductive material may be directly deposited to pixel locations to form individual pixels.

In some embodiments, the transparent conductive material layer may be patterned when deposited (e.g., using a shadow mask). In some embodiments, the transparent conductive material layer may be deposited in a continuous layer and patterned after deposition (e.g., using photolithography).

In other embodiments, the conductive matrix may be formed as a continuous layer and the continuous layer may be patterned to effectively form separate pixels. For example, the conductive matrix may be patterned using photolithography.

In some embodiments, a semiconductive matrix may be formed instead of a conductive matrix. For example, the transparent material may comprise a transparent semiconductive material layer. In some embodiments, a transparent semiconductive material layer may comprise semiconducting oxides.

The electrodes (e.g., conductive features 104a and 106a) are disposed in electrical communication with the conductive matrix. The electrodes may comprise any suitable conductive material (e.g., metal). The electrodes may be on a same side of the conductive matrix. In some embodiments, the electrodes and/or the dielectric layer 112 are chemically mechanically polished (CMP). For example, electrodes may be formed by depositing a layer of conductive material, such as copper, on a substrate comprising the dielectric layer 112 having openings formed therein and removing an overburden of the conductive material using a CMP process. In some embodiments, the electrodes may be formed by depositing the electrodes in openings of the dielectric layer 112 formed to expose portions of the conductive matrix. In some embodiments, the electrodes may be formed by depositing the layer of conductive material on a substrate comprising the dielectric layer 112 patterned to expose portions of the conductive matrix, and removing an overburden of the conductive material using a CMP process.

In some embodiments, a graphene sheet or layer may be formed between the electrodes and the conductive matrix to improve carrier transport. For example, a graphene sheet may be formed between the electrodes (e.g., conductive features 104a and 106a) the conductive matrix.

In some embodiments, an optional electron transport layer (ETL, e.g., TiOx, ZnO) or a hole transport layer (e.g., p-type polymer) may be deposited between the electrodes (e.g., conductive features 104a and 106a) and the conductive matrix to improve carrier transport and injection.

In some embodiments, at least one transparent conductive layer is embedded within the conductive matrix. One or more transparent conductive layers may be one or more electrodes.

In some embodiments, a dielectric layer may be formed on the conductive matrix.

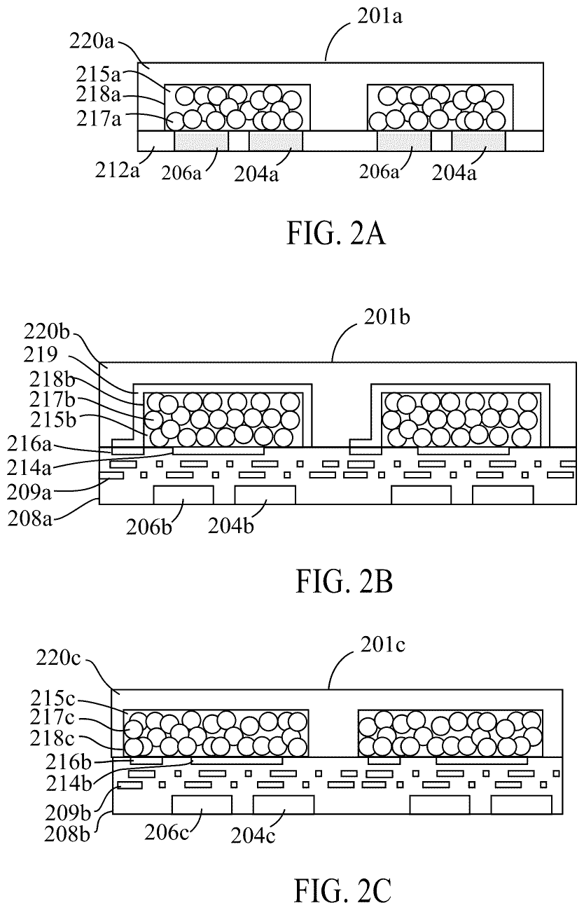

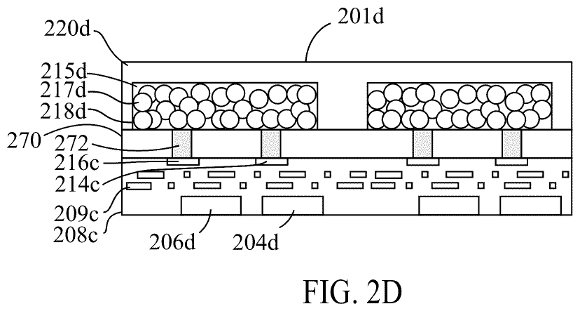

In some embodiments, the electrodes (e.g., conductive features 104a and 106a) of FIG. 1A may be electrically connected to bond pads via interconnects in an interconnect layer. For example, the electrodes of FIG. 1A may not comprise bond pads and may instead be electrically connected to bond pads (e.g., conductive features 204b and 206b) via interconnects (e.g., interconnects 209a) in an interconnect layer (e.g., interconnect layer 208a) as described in relation to FIG. 2B. In some embodiments, the electrodes (e.g., conductive features 104a and 106a) and conductive matrix may be adjacent to a semiconductor layer that is adjacent to an interconnect layer. For example, the electrodes (e.g., conductive features 104a and 106a) of FIG. 1A may not comprise bond pads and instead be electrically connected to electrode contacts (e.g., electrode contacts 214c and 216c) through vias (e.g., vias 272) in the semiconductor layer (e.g., semiconductor layer 270) as described in relation to FIG. 2D. For example, the semiconductor layer (e.g., semiconductor layer 270) may comprise pixel transistors that control electrical signals from pixel sensors of the image sensor, and the electrode contacts may be electrically connected to bond pads (e.g., conductive features 204d and 206d) through interconnects (e.g., interconnects 209c) in the interconnect layer (e.g., interconnect layer 208c) as described in relation to FIG. 2D.

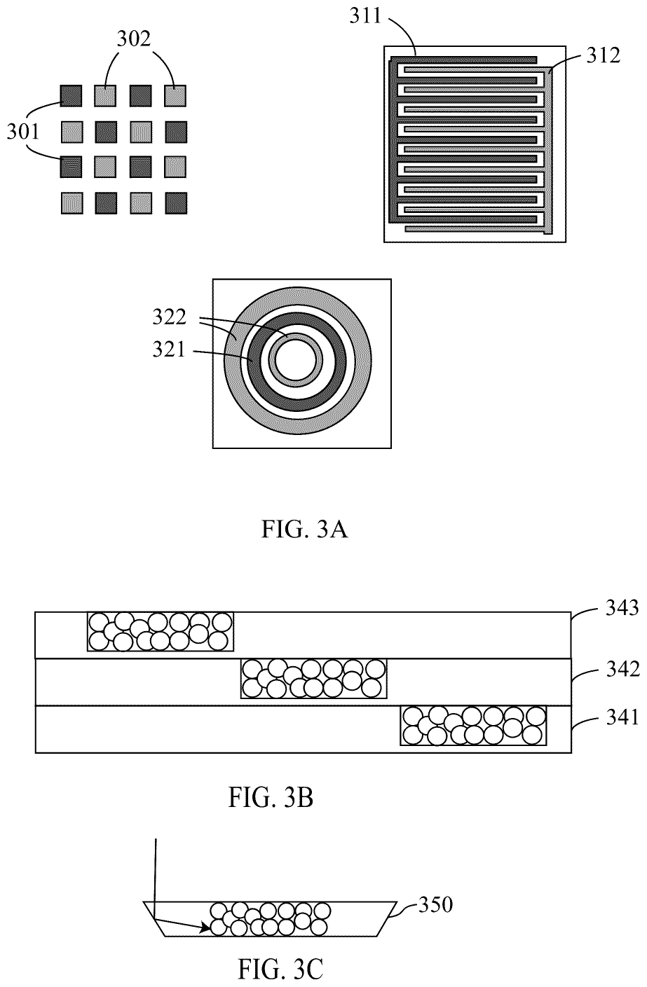

In some embodiments, the electrodes (e.g., conductive features 104a and 106a) or any suitable electrodes described in the present disclosure (e.g., electrodes 141, 143, and 145 of FIG. 1B, etc.) may be comprise the electrode arrangements shown in FIG. 3A. For example, the electrodes (e.g., conductive features 104a and 106a) may comprise a rectangular array comprising alternating first electrodes (e.g., electrodes 301) and second electrodes (e.g., electrodes 302) as described in relation to FIG. 3A. For example, the electrodes (e.g., conductive features 104a and 106a) may comprise a first electrode (e.g., electrode 311) and a second electrode (e.g., electrode 312) interdigitated with the first electrode as described in relation to FIG. 3A. For example, the electrodes (e.g., conductive features 104a and 106a) may comprise alternating concentric rings of one or more first electrodes (e.g., electrode 321) and second electrode (e.g., electrode 322) when viewed from top down or bottom up as described in relation to FIG. 3A. Although a few variations of electrode placements are shown in FIG. 3A, any suitable placement of electrodes and distribution of first electrodes 301 and second electrodes 302 can be provided that could generate uniform electric field to move the photogenerated carriers to respective electrode(s).

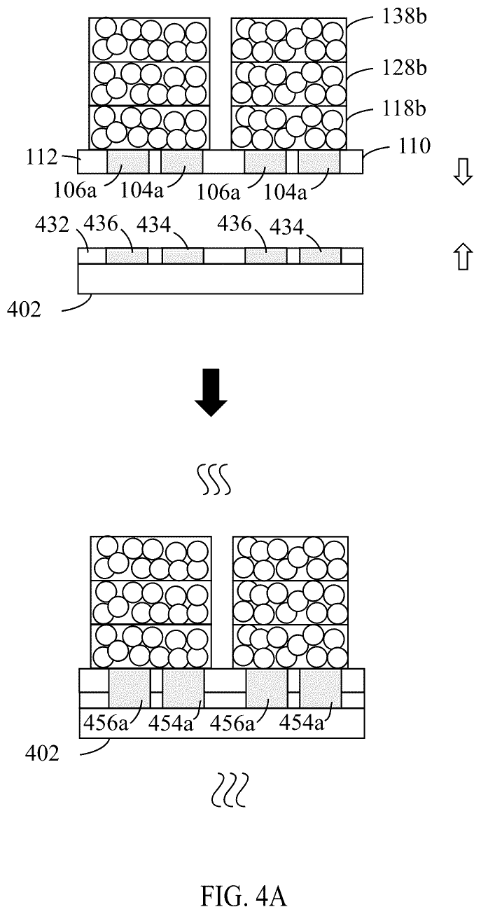

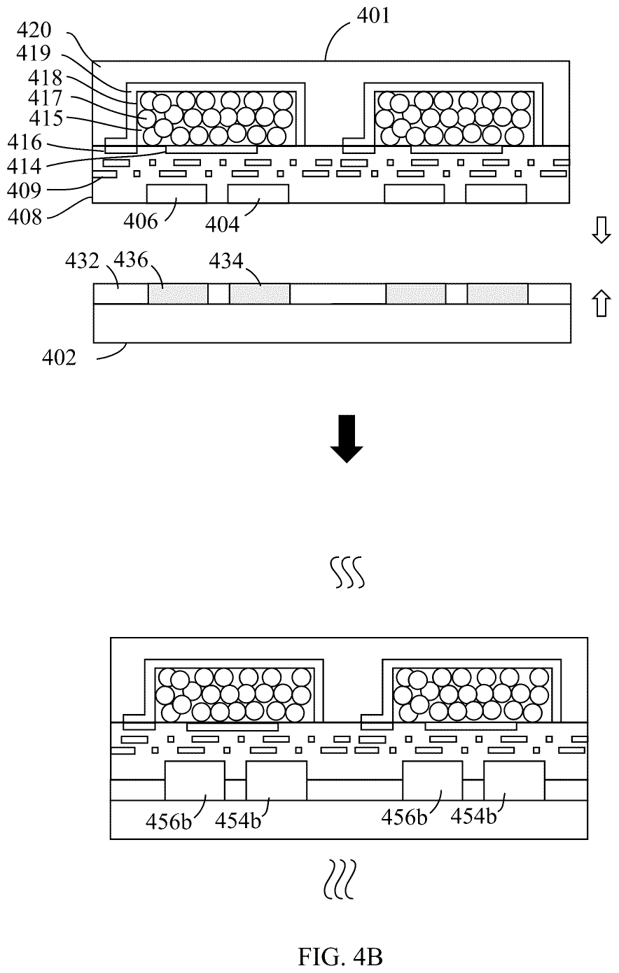

In some embodiments, at least one quantum dot substrate 118a, 128a, and 138a of FIGS. 1A, 1B comprises a sensor with a top electrode (e.g., sensor 401 with a top electrode 419 of FIG. 4B).

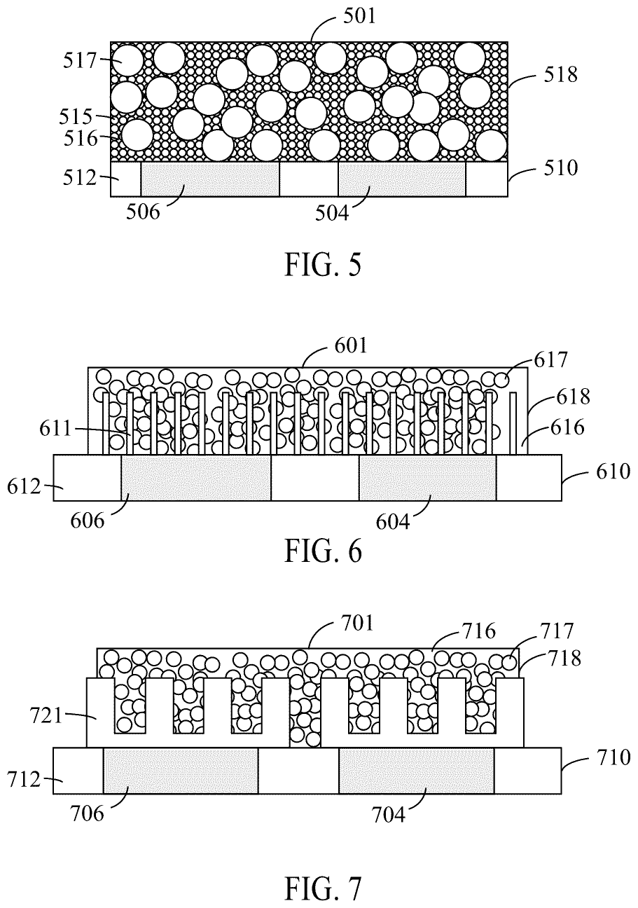

In some embodiments, the conductive matrix may further comprise conductive particles in the transparent conductive material layer. For example, the conductive particles may be similar to the ones described in FIG. 5 (e.g., embodiment with conductive particles 515 embedded in a transparent material layer 516 that is a transparent conductive material layer).

In some embodiments, at least one quantum dot substrate 118a, 128a, and/or 138a comprises quantum dots in a dielectric material or a non-conductive material. In some embodiments, at least one quantum dot substrate 118a, 128a, and/or 138a comprises a transparent conductive matrix comprising conductive particles in transparent non-conductive material layer (e.g., conductive particles 515 in a transparent material layer 516 of FIG. 5 that is a transparent non-conductive material layer).

In some embodiments, at least one quantum dot substrate 118a, 128a, and/or 138a comprises conductive structures (e.g., conductive structures 611 of FIG. 6). In some embodiments, at least one quantum dot substrate 118a, 128a, and/or 138a comprises porous conductive structures (e.g., porous conductive structures 721 of FIG. 7).

In some embodiments, at least one quantum dot substrate 118a, 128a, and/or 138a may be formed on or transferred to a separate carrier (e.g., substrate or temporary carrier). For example, the first quantum dot film 118a may be formed on a substrate 110, and the second quantum dot substrate 128a and the third quantum dot substrate 138a may be formed on separate temporary carriers. The temporary carriers may be removed after bonding one quantum dot substrate to another quantum dot substrate. For example, the second quantum dot substrate 128a may be handled using a temporary carrier and bonded to the first quantum dot substrate 118a. After bonding the first and second quantum dot substrates 118a and 128a, the temporary carrier can be removed from the second quantum dot substrate 128a. The third quantum dot substrate 138a may be bonded to a surface of the bonded first and second quantum dot substrates 118a, 128a. After bonding, the third quantum dot substrate 138a to the bonded first and second quantum dot substrates 118a, 128a, the temporary carrier coupled to the third quantum dot substrate 138a may be removed (e.g., third quantum dot substrate 138a may be released from a temporary carrier).

In some embodiments, at least one quantum dot substrate 118a, 128a, and/or 138a include electrodes, dielectric layers, interconnect layers, interconnects in insulating material, through vias in the insulating material, contacts, semiconductor layer, and/or conductive features or bond pads. For example, FIG. 1B shows a first quantum dot substrate 118c (e.g., first substrate) including bond pads (e.g., conductive features 104b1, 106b1, 104b2, 106b2, 104b3, 106b3), a dielectric layer 113, electrodes 141, vias 142, a dielectric layer 119 with conductive features 104c1, 106c1, 104c2, 106c2 disposed in the dielectric layer 119. The second quantum dot substrate 128c includes bond pads (e.g., conductive features 124a1, 126a1, 124a2, 126a2), a dielectric layer 123, electrodes 143, vias 144, a dielectric layer 129 with conductive features 126b, 124b, disposed in the dielectric layer 129. The third quantum dot substrate 138c includes bond pads (e.g., conductive features 134, 136), a dielectric layer 133, and electrodes 145. In some embodiments, at least one quantum dot substrate 118a, 128a, and/or 138a includes an active semiconductor layer with pixel transistors to capture and process the charge collected by quantum dot layer (e.g. amp select amplifiers, set/reset amplifiers, pixel select switches, ADC, memory blocks, charge storage capacitors).

In some embodiments, the first quantum dot substrate 118c (e.g., first substrate) comprises a first conductive matrix comprising quantum dots 117 disposed in a transparent material 115 (e.g., a first transparent conductive material). The second quantum dot substrate 128c (e.g., second substrate) may comprise a second conductive matrix comprising quantum dots 127 disposed in a transparent material 125 (e.g., a second transparent conductive material). The third quantum dot substrate 118c (e.g., third substrate) may comprise a third conductive matrix comprising quantum dots 137 disposed in a transparent material 135 (e.g., a third transparent conductive material).

At block 12, the multiple quantum dot substrates may be bonded together to form a stacked image sensor. The quantum dot substrates may be bonded together using direct or hybrid bonding of optically transparent substrates. For example, each quantum dot substrate may include optically transparent conductive features disposed in an optically transparent non-conductive layer, that may be bonded to other quantum dot substrates with optically transparent conductive features disposed in an optically transparent non-conductive layer. The optically transparent non-conductive layer in different quantum dot substrates may comprise a same material or a different material (e.g., materials having different elemental constituents and/or different stoichiometries; different alloys). The optically transparent non-conductive layer in different quantum dot substrates may comprise a same material or a different material (e.g., materials having different elemental constituents and/or different stoichiometries).

The optically transparent non-conductive layer may be an electrically insulative material and can comprise an optically transparent dielectric material (e.g., an inorganic dielectric material), examples of which include, but are not limited to: semiconductor oxides, semiconductor nitrides, silicon oxide (SiO₂), silicon nitride (SiNₓ; Si₃N₄). The optically transparent conductive features may be an electrically conductive material and can comprise an optically transparent and electrically conductive material, examples of which include, but are not limited to: doped and undoped metal oxides, aluminum zinc oxide (AZO), indium tin oxide (ITO; In₂O₃), zinc oxide (ZnO), zinc tin oxide (ZnSnO₃; Zn₂SnO₄), indium-doped zinc oxide (IZO), indium oxide, cadmium tin oxide (Cd₂SnO₄), tin oxide (SnO₂), titanium dioxide (TiO₂), niobium-doped titanium dioxide (Nb—TiO₂), titanium nitride (TiN), and transition metal nitrides comprising a IIIB, IVB, or VB transition metal.

In some embodiments, the optically transparent non-conductive layer or optically transparent conductive features may comprise multiple layers. For example, an underlying layer may be too rough (e.g., not smooth enough) for direct bonding, and a surface layer (e.g., on top of the underlying layer) may be used to facilitate direct bonding between the layers of different quantum to films. A surface layer can comprise a metal or polysilicon layer that is sufficiently thin (e.g., less than or equal to 50 nanometers) so that the metal or polysilicon layer is optically transparent (e.g., semitransparent) while being electrically conductive. Examples of metals for the metal layers compatible with certain implementations described herein include, but are not limited to: metal elements (e.g., gold, silver, aluminum, copper, iridium, iron, nickel, osmium, palladium, platinum, rhenium, rhodium, ruthenium, zinc) and electrically conductive alloys that include one or more of these metal elements. In some embodiments, both or one layer of different quantum dot films to be bonded can comprise multiple layers. In some embodiments, the surface layer can comprise the same metal or polysilicon material or can comprise different metal or polysilicon materials (e.g., materials having different elemental constituents and/or different stoichiometries; different alloys).

In some embodiments, the conductive features 106a comprise an electrically conductive material that is optically transparent (e.g., indium tin oxide (ITO), indium-doped zinc oxide (IZO), tin oxide (SnO₂)) or optically semi-transparent (e.g., metal or polysilicon layer having a thickness less than 50 nanometers). Accordingly, as explained herein, the conductive features 106a can comprise conductive oxide materials in various implementations.

As described herein, some electrically conductive oxides (e.g., indium tin oxide or ITO) or nitrides have the ability to self-bond at modest temperatures (e.g., in a range of 75° C. to 400° C.; in a range of 120° C. to 300° C.; in a range of 150° C. to 300° C.). In certain implementations, use of electrically conductive oxide or nitride layers can simplify processes for bonding (e.g., blanket wafer and hybrid bonding surfaces) by omitting one or more other processing steps (e.g., planarization and/or surface activation). For example, the electrically conductive oxide or nitride layers can be self-leveled if planarized before patterning. In conjunction with certain layout structures, such electrically conductive oxide or nitride layers can be used to bond multiple input/output components with a single material interface. For example, ITO can be used to bond two substrates without a surface activation step, and in certain implementations, without a surface planarization (e.g., chemical-mechanical polishing or CMP) step. The electrically conductive oxide or nitride layers can also allow bonding at modest temperatures (e.g., less than 300° C.) and can be used for surface mounting. In view of the electrical conductivity, such layers can provide electromagnetic shielding for other components of the electronic packages. In addition, because certain such materials are substantially optically transparent, they can be used for bonding optoelectronic applications, as well as in other structures where photon transmission is not a factor.

In some embodiments, an interface layer (e.g., an electrically conductive oxide material) is patterned such that the at least one first region of the interface layer on a conductive feature (e.g., optically transparent conductive feature) is electrically isolated from the at least one second region of the interface layer on a non-conductive layer (e.g., optically transparent non-conductive layer). For example, there may be gaps between the at least one first region and the at least one second region. In certain implementations, the gaps comprise gas (e.g., air; nitrogen) and can be at atmospheric pressure, less than atmospheric pressure (e.g., vacuum pressure), or greater than atmospheric pressure. In certain implementations, dielectric material may fill the gaps between the at least one first region and the at least one second region.

In some embodiments, conductive oxide material and/or solid dielectric material may be at a periphery of pixels or quantum dot films to hermetically seal the pixels or quantum dot films from the ambient environment. In certain implementations, the solid dielectric material (e.g., silicon oxycarbonitride or SiOₓN_{y}C_{z}) provides higher hermeticity (e.g., lower gas leak rate) than would the electrically conductive oxide material.

At block 13, the bonded films are patterned into patterned quantum dot substrates (e.g., first quantum dot substrate 118b, second quantum dot substrate 128b, and third patterned dot film 138b). For example, patterning the bonded films may be used to isolate pixels of an image sensor for each pair of electrodes (e.g., bond pads or conductive features 104a, 106a). For example, the method may include forming pixel stacks of the stacked image sensor (e.g., stacked sensor, stacked sensor pixel) by removing portions of a stacked conductive matrix (e.g., first conductive matrix, second conductive matrix, and third conductive matrix). In some embodiments, the image sensor comprises a plurality of sensors (e.g., photodiodes, two or more photodiodes, e.g., thousands of photodiodes, or millions of photodiodes) although two are shown at block 13 in FIG. 1A.

FIG. 1B is an illustrative schematic of sectional side views of forming a stacked quantum dot image sensor to illustrate aspects of the method, in accordance with embodiments of the present disclosure. The quantum dot image sensor of FIG. 1B may be similar to the quantum dot image sensor of FIG. 1A described above, and therefore the description of similar features is omitted for brevity. In some embodiments, FIG. 1B may show a portion of a quantum dot image sensor such as a single pixel. In some embodiments, FIG. 1B may show a quantum dot image sensor, but for simplicity, the patterning of the pixels may not be shown.

In some embodiments, the quantum dot films (e.g., first quantum dot substrate 118c, second quantum dot substrate 128c, third quantum dot substrate 138c) in FIG. 1B may be the same as quantum dot substrates in FIG. 1A, except the quantum dot substrates in FIG. 1B may show more detail as a zoomed in view of the quantum dot substrates. For example, a first quantum dot substrate 118c, a second quantum dot substrate 128c, a third quantum dot substrate 138c, and bond pads (e.g., conductive features 104b1-3, 106b1-3) of FIG. 1B may correspond to (e.g., be the same or similar to) the first quantum dot substrate 118a or 118b, the second quantum dot substrate 128a or 128b, the third quantum dot substrate 138a or 138b, and bond pads (e.g., conductive features 106a, 104a) of FIG. 1A.

In some embodiments, the third quantum dot substrate 138c (e.g., top quantum dot substrate) comprises a transparent conductive matrix (e.g., quantum dots 137 in a transparent material layer 135). The transparent conductive matrix is disposed on electrodes 145. The electrodes 145 may be various shapes and sizes and may be electrically connected to bond pads (e.g., conductive features 136, 134). The electrodes 145 and bond pads may be disposed in a transparent material layer. In some embodiments the transparent material layer may be non-conductive, dielectric, or insulating material layer. For example, the transparent material layer is a dielectric layer 133. In some embodiments, the third quantum dot substrate 138c may further comprise an interconnect layer comprising interconnects. For example, interconnects may be disposed in the dielectric layer 133 and one or more interconnects may electrically connect one or more electrodes 145 of the third quantum dot substrate 138c to a corresponding bond pad (e.g., conductive features 134, 136) of the third quantum dot substrate 138c. In some embodiments, the bond pads and the electrodes comprise a transparent conductive material such as any suitable transparent conductive material mentioned in the present disclosure.

In some embodiments, a second quantum dot substrate 128c (e.g., intermediate quantum dot substrate) comprises a transparent conductive matrix (e.g., quantum dots 127 disposed in a transparent material layer 125). The transparent conductive matrix may be disposed between two transparent material layers. The transparent material layers may be non-conductive, dielectric, or insulating material layer. For example, the transparent material layers may be transparent dielectric layers (e.g., dielectric layer 129 and dielectric layer 123). A dielectric layer 129 (e.g., top dielectric layer) and bond pads (e.g., conductive features 124b and 126b) disposed in the dielectric layer 129 may be disposed on the transparent conductive matrix of the second quantum dot substrate 128c. The transparent conductive matrix of the second quantum dot substrate 128c may be disposed on electrodes 143. The electrodes 143 may be various shapes and sizes and may be electrically connected to bond pads (e.g., conductive features 124a2, 126a2). The electrodes 143 and bond pads may be disposed in a dielectric layer 123. In some embodiments, the second quantum dot substrate 128c may further comprise an interconnect layer comprising interconnects. For example, interconnects may be disposed in the dielectric layer 123 and one or more interconnects may electrically connect one or more electrodes 143 of the second quantum dot substrate 128c to a corresponding bond pad (e.g., conductive features 124a2, 126a2) of the second quantum dot substrate 128c. In some embodiments, the bond pads and the electrodes comprise a transparent conductive material such as any suitable transparent conductive material mentioned in the present disclosure.

In some embodiments, a first quantum dot substrate 118c (e.g., bottom quantum dot substrate) comprises a transparent conductive matrix (e.g., quantum dots 117 disposed in a transparent material layer 115). The transparent conductive matrix may be disposed between two transparent material layers. The transparent material layers may be non-conductive, dielectric, or insulating material layer. For example, the transparent material layers may be transparent dielectric layers (e.g., dielectric layer 119 and dielectric layer 113). A dielectric layer 119 (e.g., top dielectric layer) and bond pads (e.g., conductive features 104c1-2, 106c1-2) disposed in the dielectric layer 119 may be disposed on the transparent conductive matrix of the second quantum dot substrate 118c. The transparent conductive matrix of the first quantum dot substrate 118c may be disposed on electrodes 141. The electrodes 141 may be various shapes and sizes and may be electrically connected to bond pads (e.g., conductive features 104b3, 106b3). The electrodes 141 and bond pads may be disposed in a dielectric layer 113. In some embodiments, the second quantum dot substrate 118c may further comprise an interconnect layer comprising interconnects. For example, interconnects may be disposed in the dielectric layer 113 and one or more interconnects may electrically connect one or more electrodes 141 of the first quantum dot substrate 118c to a corresponding bond pad (e.g., conductive features 106b3, 104b3) of the first quantum dot substrate 118c. In some embodiments, the bond pads and the electrodes comprise a transparent conductive material such as any suitable transparent conductive material mentioned in the present disclosure. In some embodiments, at least one quantum dot substrate 118c, 128c, and/or 138c or at least one dielectric layer (e.g., dielectric layer 113, 123, 133) or at least one of top dielectric layers (e.g., dielectric layer 119, 129) can include an active semiconductor layer that could be continuous or partial with pixel transistors to capture and process the charge collected by quantum dot layer(s).

The electrodes 141, 143, and 145 may be various shapes and sizes that are electrically connected to corresponding bond pads in a respective quantum dot layer. In some embodiments, an interconnect layer comprising interconnects in a transparent insulating material electrically connect the electrodes to the bond pads via the interconnects. For example, signals (e.g., photogenerated carriers generated by absorbing red light from quantum dots 137 collected at electrodes 145) may go to the bond pads (e.g., conductive features 136, 134). Signals (e.g., photogenerated carriers generated by absorbing blue light from quantum dots 127 collected at electrodes 143) may go to the bond pads (e.g., conductive features 126a2, 124a2). Signals (e.g., photogenerated carriers generated by absorbing green light from quantum dots 117 collected at electrodes 141) may go to the bond pads (e.g., conductive features 106b3, 104b3).

In some embodiments the electrodes 141, 143, and/or 145 comprise a transparent conductive material such as any suitable transparent conductive material such as those mentioned in the present disclosure. In some embodiments, the electrodes 141 comprise any suitable conductive material (e.g., metal, copper). In some embodiments, the conductive features 106b1-3, 104b1-3, 106c1-2, 104c1-2, 126a1-2, 124a1-2, 126b, 124b, 136, and/or 134 comprise a transparent conductive material such as any suitable transparent conductive material such as those mentioned in the present disclosure. In some embodiments, the conductive features 106b1-3, 104b1-3 comprise any suitable conductive material (e.g., metal, copper). In some embodiments, the dielectric layers 133, 129, 123, 119, and 113 may comprise any suitable transparent non-conductive material such as those mentioned in the present disclosure.

In some embodiments, the second quantum dot substrate 128c comprises through substrate vias (TSV) or through vias 144. The through vias 144 are formed of a conductive material. In some embodiments, the through vias 144 are formed of transparent conductive material. The through vias 144 may be electrically isolated to not short to the quantum dots 127 or the transparent conductive material (e.g., transparent material 125). For example, an insulating material may cover a surface of the through vias 144 to electrically isolate the through vias 144. The through vias 144 may be electrically isolated to not short to the electrodes 143. In some embodiments, the through vias 144 may contact transparent conductive material (e.g., interconnects) disposed in the transparent non-conductive dielectric layer 123 that connect to bond pads (e.g., conductive features 126a1, 124a1, 126a2, 124a2). The through vias 144 may electrically connect the bond pads (e.g., conductive features 126b, 124b) to bond pads (e.g., conductive features 126a1, 124a1). The through vias 144 may electrically connect to the bond pads (e.g., conductive features 126a1, 124a1) through interconnects in an insulating material of an interconnect layer. Signals from the quantum dot substrate 128c may be collected at the electrodes 143 and go to the bond pads (e.g., conductive features 126a2, 124a2). In some embodiments, through vias 144 formed in the second quantum dot substrate 128c may be used to collect the charge generated in the first quantum dot substrate 138c and collected by electrodes 145. The through vias 144 (e.g., TSVs) collect the generated charges via electrodes 145, through corresponding bond pads (e.g., conductive features 136, 134) towards the processor at the bottom (e.g., through to conductive features 106c1, 104cl to TSVs 142 in first quantum dot substrate 118c that are below TSVs 144 and then to conductive features 106b1, 104b1).

In some embodiments, the first quantum dot substrate 118c comprises TSVs or through vias 142. The through vias 142 are formed of a conductive material. In some embodiments, the through vias 142 are formed of transparent conductive material. The through vias 142 may be electrically isolated to not short to the quantum dots 117 and the transparent conductive material 115. For example, an insulating material may cover a surface of the through vias 142 to electrically isolate the through vias 142. The through vias 142 may be electrically isolated to not short to the electrodes 141. In some embodiments, the through vias 142 may contact transparent conductive material (e.g., interconnects) disposed in the transparent non-conductive dielectric layer 113 that connect to bond pads (e.g., conductive features 106b1-2, 104b1-2).

In some embodiments, the through vias 142 directly below and connected to bond pads or conductive features 106c1, 104cl may electrically connect to the bond pads or conductive features 106b1, 104b1. The through vias 142 may electrically connect the bond pads 106c1, 104cl to the bond pads 106b1 and 104b1 through interconnects in an insulating material of an interconnect layer. In some embodiments the interconnects may be a transparent, a semi-transparent, or a non-transparent conductive material. Charges generated in the third quantum dot substrate 138c may be collected at the electrodes 145, passed to conductive features 136 and 134 to conductive features 126b, 124b (e.g., interconnects 194 and 196), through TSV or through vias 144, to conductive features 126a1, 124al to conductive features 106c1, 104cl (e.g., interconnects 184 and 186), through TSV or through vias 142, to conductive features 106b1, 104b1 that may go towards a processor below the stacked quantum dot sensor (e.g., image processor device 402 of FIG. 4A).

In some embodiments, the through vias 142 directly below and connected to bond pads or conductive features 106c2, 104c2 may electrically connect to bond pads or conductive features 106b2, 104b2. The through vias 142 may electrically connect the bond pads 106c2, 104c2 to the bond pads 106b2 and 104b2 through interconnects in an insulating material of an interconnect layer. In some embodiments the interconnects may be a transparent, a semi-transparent, or a non-transparent conductive material. Charges generated in the second quantum dot substrate 128c may be collected by electrodes 143, passed to conductive features 126a2, 124a2 to conductive features 106c2, 104c2 (e.g., interconnects 174 and 176), through TSV or through via 142, to conductive features 106b2, 104b2 that may go towards a processor below the stacked quantum dot sensor (e.g., image processor device 402 of FIG. 4A).

In some embodiments, signals or charge generated from the quantum dot substrate 118c may be collected at electrodes 141 and go to the bond pads (e.g., conductive features 106b3, 104b3) that may go towards a processor below the stacked quantum dot sensor (e.g., image processor device 402 of FIG. 4A).

In some embodiments, the vias may comprise a non-transparent material. In some embodiments, vias (e.g., vias 142 and 144) may be formed in regions adjacent to the photodiodes shown in FIGS. 2A-2D.

In some embodiments, the bond pads (e.g., conductive features 106b, 104b) and the electrodes 141 comprise a non-transparent material. For example, bond pads (e.g., conductive features 106b, 104b) and electrodes 141 may comprise a copper material.

The quantum dot films (e.g., first quantum dot substrate 118c, second quantum dot substrate 128c, and third quantum dot substrate 138c) may be direct bonded or hybrid bonded. In some embodiments, ZiBond and/or TSVs formed using a via-last method may be implemented for connections at all levels. Electrodes 145 may be electrically connected to bond pads (e.g., conductive features 106b1 and 104b1 on the left side of FIG. 1B), and electrodes 143 may be electrically connected to bond pads (e.g., conductive features 106b2 and 104b2 in the center of FIG. 1B). Electrodes 141 may be electrically connected to bond pads (e.g., conductive features 106b3 and 104b3 in the right side of FIG. 1B). The generated photo carriers from each substrate may be processed separately and carried to the processor without mixing with the generated photo carriers of the other substrates. For example, generated photo carriers, generated charge, or signals from the third quantum dot substrate 138c may be collected at electrodes 145 and go to the bond pads (e.g., conductive features 106b1 and 104b1 on the left side of FIG. 1B) of the first quantum dot substrate 118c to be carried to the processor without mixing with the carriers of the other substrates. Generated photo carriers, generated charge, or signals from the second quantum dot substrate 128c may go to the bond pads (e.g., conductive features 106b2 and 104b2 in the center of FIG. 1B) of the first quantum dot substrate 118c to be carried to the processor without mixing with the carriers of the other substrates. Generated photo carriers, generated charge, or signals from first quantum dot substrate 118c may go to the bond pads (e.g., conductive features 106b3 and 104b3 in the right side of FIG. 1B).

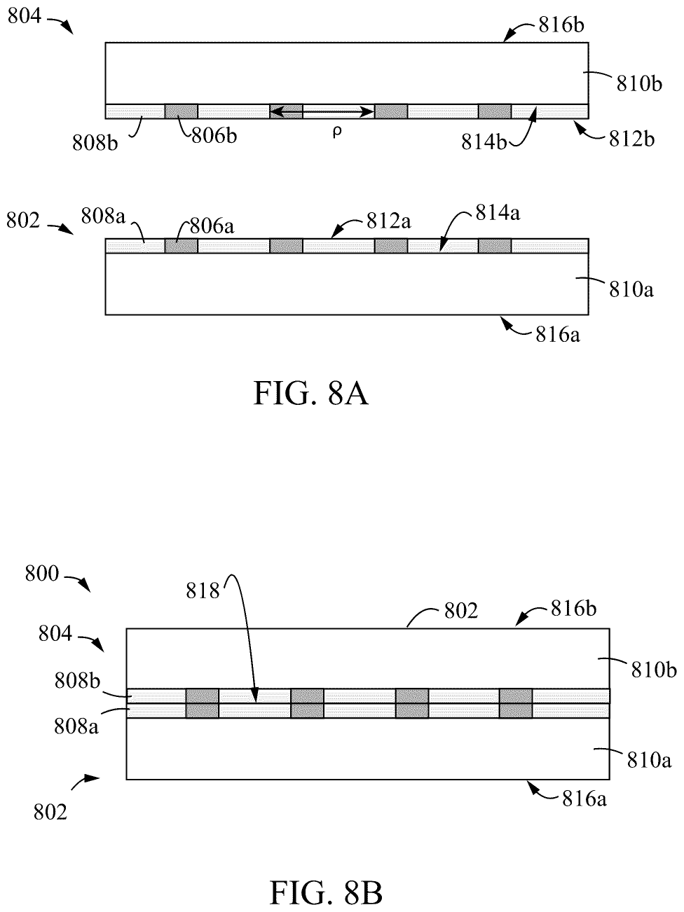

In some embodiments, the stacked image sensor is formed by hybrid bonding of quantum dot substrates comprising bond pads or conductive features disposed in dielectric layers on one or more surfaces of a corresponding matrix comprising quantum dots. The stacked image sensor may be formed using any suitable processes for hybrid bonding of substrates such as those described in the present disclosure (e.g., hybrid bonding substrates of FIG. 1A and hybrid bonding substrates of FIGS. 8A and 8B).

In some embodiments, the method may include aligning the bond pads (e.g., conductive features 106c1, 104c1, 106c2, 104c2) of a first substrate (e.g., first quantum dot substrate 118c) with the bond pads (e.g., conductive features 126a1, 124a1, 126a2, 124a2) of a second substrate (e.g., second quantum dot substrate 128c) and contacting the substrates at ambient temperature. Here, contacting the substrates may form a workpiece where the substrates are attached to one another through direct bonds formed between the dielectric layers 119 and 123 without the use of an intervening adhesive. The method may or may include heating a workpiece to a processing temperature between about 50° C. to about 150° C. or more, or of about 150° C. or more, such as about 250° C. or more, or about 300° C. or more, or to a temperature less than about 300° C., or less than about 250° C. to form direct interconnects 184 and 186 via hybrid bonding of the bond pads (e.g., conductive features 104c1 and 106c1) to bond pads (e.g., conductive features 126al and 124a1), and to form direct interconnects 174 and 176 via hybrid bonding of the bond pads (e.g., conductive features 104c2 and 106c2) to bond pads (e.g., conductive features 126a2 and 124a2). In some embodiments, the method may include heating the workpiece to moderate temperatures such as those described in the present disclosure (e.g., interconnects 174, 176, 184 and 186 may be formed without heating above the conductive materials' melting temperature).

In some embodiments, the method may include aligning the bond pads (e.g., conductive features 136, 134) of a third substrate (e.g., third quantum dot substrate 138c) with the bond pads (e.g., conductive features 126b, 124b) of a second substrate (e.g., second quantum dot substrate 128c or the bonded second quantum dot substrate 128c to the first quantum dot substrate 118c) and contacting the substrates at ambient temperature. Here, contacting the substrates may form a workpiece where the substrates are attached to one another through direct bonds formed between the dielectric layers 133 and 129 without the use of an intervening adhesive. The method may include heating the workpiece to a processing temperature between about 50° C. to about 150° C. or more, or of about 150° C. or more, such as about 250° C. or more, or about 300° C. or more, or to a temperature less than about 300° C., or less than about 250° C. to form direct interconnects 194 and 196 via hybrid bonding of the bond pads (e.g., conductive features 134 and 136) to bond pads (e.g., conductive features 126b and 124b). In some embodiments, the method may include heating the workpiece to moderate temperatures such as those described in the present disclosure (e.g., interconnects 194 and 196 may be formed without heating above the conductive materials' melting temperature).

FIG. 2A is an illustrative schematic sectional side view of an image sensor 201a with a conductive matrix 218a, in accordance with embodiments of the present disclosure. As shown in FIG. 2A, the conductive matrix 218a is be patterned. Image sensor 201a comprises electrodes 204a and 206a in a first dielectric layer 212a, conductive matrix 218a on the electrodes 204a and 206a, and a second dielectric layer 220a. The conductive matrix 218a comprises quantum dots 217a in a transparent conductive material layer 215a The image sensor 201a may be substantially similar to the image sensor as described above in relation to FIG. 1A (e.g., quantum dot substrate 118a, 128a, 138a comprising an image sensor with a conductive matrix), except that a second dielectric layer 220a is formed on the conductive matrix and portions of the dielectric layer 112. The image sensor 201a of FIG. 2A shows an example of two sensor pixels (e.g., photodiodes) instead of the example of a single sensor pixel shown in FIG. 1A.

The method may include depositing a second dielectric layer 220a on the conductive matrix 218a. The second dielectric layer 220a may serve as a barrier or encapsulation layer to protect the quantum dots from oxidation. The second dielectric layer 220a may comprise an oxide material. The second dielectric layer 220a may comprise a material transparent to wavelengths to be detected by the image sensor 201a (e.g., infrared (IR), near IR (NIR), short wave IR (SWIR), visible, or any suitable wavelength range). For example, if the image sensor 201a detects short wave infrared (SWIR) wavelengths, the second dielectric layer 220a may be transparent to wavelengths of the SWIR range. If the image sensor 201a detects a visible range, the second dielectric layer 220a may be transparent to wavelengths in the visible range. In some embodiments, the second dielectric layer 220a may comprise two or more dielectric layers. In other embodiments, additional sealing layer may be deposited (e.g. for further mechanical or environmental protection). For example, the second dielectric layers may comprise one or more layers of silicon oxide, silicon nitride, etc. In some embodiments, the dielectric layers may be polished after deposition to form non-wavy (e.g., smooth) top surface for further deposition of other layers or devices (e.g. polymer lenses, color filters, infrared filters, etc.). In some embodiments, other layers or devices may be formed overlaying second dielectric layer(s) 220a.

In some embodiments, a sealing/barrier film is used in place of the second dielectric layer 220a. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the second dielectric layer 220a or sealing/barrier film is optional. For example, the transparent conductive material layer 215a may protect the quantum dots 217a from oxidation. As another example, the conductive matrix 218a may comprise conductive particles in a transparent insulating material layer (e.g., polymer) instead of transparent conductive material layer 215a, and the transparent insulating material layer may protect the quantum dots from environmental exposure.

FIG. 2B is an illustrative schematic sectional side view of an image sensor 201b with a conductive matrix 218b, in accordance with embodiments of the present disclosure. The image sensor 201b comprises an interconnect layer 208a comprising bond pads (e.g., conductive features 204b and 206b), interconnects 209a disposed in an insulating material, and electrodes 214a and 216a, a conductive matrix 218b, top electrode (e.g., transparent conductive layer 219), and a dielectric layer 220b. The conductive matrix 218b comprises quantum dots 217b in a transparent conductive material layer 215b. The image sensor 201b may be substantially similar to the image sensor 201a described above in relation to FIG. 2A, except the sensor 201b includes the interconnect layer 208a and the top electrode (e.g., transparent conductive layer 219). The top electrode (e.g., transparent conductive layer 219) is electrically connected to electrode 216a. The dielectric layer 220b may be substantially similar to the dielectric layer 220a of FIG. 2A except it is on the top electrode (e.g., transparent conductive layer 219) and portions of the interconnect layer 208a. In some embodiments, the image sensor 201b may not include a dielectric layer 220b.

In some embodiments, a sealing/barrier film is used in place of the dielectric layer 220b. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the dielectric layer 220b or sealing/barrier film is optional. For example, the transparent conductive material layer 215b may protect the quantum dots 217b from environmental exposure. As another example, the conductive matrix 218b may comprise conductive particles in a transparent insulating material layer (e.g., polymer) instead of transparent conductive material layer 215b, and the transparent insulating material layer may protect the quantum dots from environmental exposure.

The electrodes 214a and 216a are electrically connected to bond pads (e.g., conductive features 204b and 206b), respectively, via interconnects 209a in the interconnect layer 208a. In some embodiments, a first electrode 214a is a negative electrode and a second electrode 216a is a positive electrode. In some embodiments, the first electrode 214a and the second electrode 216a are planar to a surface of the interconnect layer 208a. In some embodiments, the second electrode 216a further comprises the transparent conductive layer 219. The first electrode 214a is in contact with at least a portion of a first surface of the conductive matrix 218b, and the second electrode 216a (e.g., further comprising the transparent conductive layer 219) is in contact with a second surface of the conductive matrix 218b opposite the first surface.

A method of forming the image sensor 201b may comprise depositing a top electrode (e.g., transparent conductive layer 219) on the conductive matrix 218b and the second electrode 216a. The transparent conductive layer 219 is patterned. For example, the transparent conductive layer 219 may be deposited and patterned (e.g., via photolithography). The transparent conductive layer 219 may be patterned when deposited (e.g., via a shadow mask). The transparent conductive layer 219 is electrically connected to the second electrode 216a, and the transparent conductive layer 219 may be referred to as an electrode or a top electrode of the sensor 201b. In some embodiments, the transparent conductive layer 219 comprises a transparent conductive oxide material (e.g., ITO).

In some embodiments, an electron transport layer (e.g., TiOx, ZnO) and/or a hole transport layer (e.g., p-type polymer) may be deposited between the respective electrodes and the conductive matrix to improve carrier transport and injection. For example, in a sensor with a top electrode, a hole transport layer may be deposited between a transparent top electrode (electrically connected to electrode 216b) and the conductive matrix 218b and an electron transport layer may be deposited between electrode 214b and the conductive matrix 218b.

In some embodiments, only one of the electrodes of a sensor may comprise first electrodes of FIG. 3A. For example, the electrodes 214a of the sensor 201b of FIG. 2B may comprise first electrodes 301, 311, or 321 of FIG. 3A.

FIG. 2C is an illustrative schematic sectional side view of an image sensor 201c with a conductive matrix 218c, in accordance with embodiments of the present disclosure. The image sensor 201c comprises an interconnect layer 208b comprising bond pads 204c and 206c, interconnects 209b in an insulating material, and electrodes 214b and 216b, a conductive matrix 218c, and a dielectric layer 220c. The conductive matrix 218c comprises quantum dots 217c in a transparent conductive material layer 215c. The image sensor 201c may be substantially similar to the image sensor 201a described above in relation to FIG. 2A, except the image sensor 201c includes an interconnect layer 208b. The interconnect layer 208b may be similar to the interconnect layer 208a described above in relation to FIG. 2B. The conductive matrix 218c may be formed on both electrodes 214b and 216b. No top electrode may be connected to electrode 216b. The dielectric layer 220c may be similar to the dielectric layer 220a, except it is on portions of the interconnect layer 208b instead portions of a first dielectric layer 212a. In some embodiments, the image sensor 201c may not include a dielectric layer 220c.

In some embodiments, a sealing/barrier film is used in place of the dielectric layer 220c. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the dielectric layer 220c or sealing/barrier film is optional. For example, the transparent conductive material layer 215c may protect the quantum dots 217c from environmental exposure. As another example, the conductive matrix 218c may comprise conductive particles in a transparent insulating material layer (e.g., polymer) instead of transparent conductive material layer 215c, and the transparent insulating material layer may protect the quantum dots from environmental exposure.

FIG. 2D is an illustrative schematic sectional side view of an image sensor 201d with a semiconductor layer 270, in accordance with embodiments of the present disclosure. The image sensor 201d comprises a conductive matrix 218d and electrodes adjacent to a semiconductor layer 270 that is adjacent to an interconnect layer 208c. The conductive matrix 218d comprises quantum dots 217d in a transparent conductive material layer 215d. The electrodes may be electrically connected to electrode contacts 214c and 216c through vias 272 in a semiconductor layer 270. The semiconductor layer 270 comprises pixel transistors that control electrical signals from pixel sensors of the image sensor 201d. The electrode contacts 214c and 216c are electrically connected to bond pads (e.g., conductive features 204d and 206d) through interconnects 209c in the interconnect layer 208c.

In some embodiments, the image sensor 201d may be substantially similar to the image sensor 201c described above in relation to FIG. 2C, except that image sensor 201d includes a semiconductor layer 270 and the interconnect layer 208c comprises electrode contacts 214c and 216c (e.g., instead of electrodes 214b and 216b of the interconnect layer 208b). For example, the image sensor 201d may include electrodes in contact with the conductive matrix 218d (e.g., similar to the electrodes 214b and 216b of FIG. 2C except the semiconductor layer 270 comprises the electrodes). The dielectric layer 220d may be similar to the dielectric layer 220a, except it is on portions of the semiconductor layer 270 instead of portions of a first dielectric layer 212a. In some embodiments, the image sensor 201d may not include a dielectric layer 220d.

In some embodiments, the conductive matrix 218d is formed on the semiconductor layer 270d providing pixel transistors between the conductive matrix 218d comprising quantum dots 217d and the bond pads (e.g., conductive features 204d and 206d). The conductive matrix 218d comprising the quantum dots 217d may act as the photodiodes (i.e. convert photons to electrical signals) and pixel transistors on the semiconductor layer 270 (e.g. silicon) may control the electrical signals. The charge created by a photo-detector may be converted to a voltage signal and may be passed on to the output amplifier through an array of row-select and column-select switches. Furthermore, an analog to digital convertor (ADC) may be formed on the semiconductor layer 270 to digitize the amplified signal. To perform readout, the pixel values of a given row may be transferred in parallel to a set of storage capacitors and then, these transferred pixel values may be read out sequentially. While the conductive matrix 218d comprising quantum dots 217d may only perform the photodetection function, the semiconductor layer(s) 270 may perform the rest of the operation. The semiconductor layer may provide the pixel circuits comprising amp transistors, select transistors, reset transistors, signal lines, ADC, pixel select switches (or row/column selects), memory blocks, capacitors, etc. to form an image sensor circuit with the conductive matrix 218d comprising quantum dots 217d.

The pixel sensor architecture may be one of several types. In an active-pixel sensor (APS) architecture, each pixel location contains not only the photodiode but also an amplifier. A simpler architecture like passive-pixel sensor (PPS) may also be implemented within the semiconductor layer that does not integrate an amplifier into each pixel. In a digital-pixel sensor (DPS) device architecture, each pixel may have its own analog-to-digital converter and memory block which allows the digital values proportional to light intensity.

In some other embodiments, pixel transistors may be a part of an image processor device. For example, pixel transistors may be part of an image processor device 402 of FIGS. 4A-4B.

In some embodiments, a sealing/barrier film is used in place of the dielectric layer 220d. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the dielectric layer 220d or sealing/barrier film is optional. For example, the transparent conductive material layer 215d may protect the quantum dots 217d from environmental exposure. As another example, the conductive matrix 218d may comprise conductive particles in a transparent insulating material layer (e.g., polymer) instead of transparent conductive material layer 215d, and the transparent insulating material layer may protect the quantum dots from environmental exposure.

FIG. 3A schematically illustrates example configuration of electrodes, in accordance with embodiments of the present disclosure. For example, the electrodes (e.g., conductive features 104a and 106a) of the image sensor of FIG. 1A, the electrodes 141, 143, and 145 of the image sensor of FIG. 1B, the electrodes 204a and 206a of image sensor 201a of FIG. 2A, the electrodes 214b and 216b of image sensor 201c of FIG. 2C, the electrodes of image sensor 201d of FIG. 2D, the electrodes of image sensor of FIG. 4A or 4B, the electrodes 504 and 506 of image sensor 501, the electrodes 604 and 606 of image sensor 601, or the electrodes 704 and 706 of image sensor 701, may comprise the electrodes 301 and 302, 311 and 312, or 321 and 322 of FIG. 3A. The distribution of first and second electrodes of FIG. 3A may enable creation of a uniform field for carriers to move efficiently.

In some embodiments, the plurality of first electrodes 301 and second electrodes 302 are in a rectangular array. Each electrode may be arranged in an alternating pattern of first and second electrodes when viewed from the top down or bottom up. The first electrodes 301 may be biased with an opposite bias of the second electrodes 302. For example, first electrodes 301 may be biased with a positive bias, and the second electrodes 302 may be biased with a negative bias. In some embodiments, the first electrodes 301 are electrically connected to a first bond pad (e.g., bond pad 204b, 204c, or 204d), and the second electrodes 302 are electrically connected to a second bond pad (e.g., bond pad 206b, 204c, or 206d) through interconnects (e.g., interconnects 209a, 209b, 209c) in an interconnect layer (e.g., interconnect layer 208a, 208b, or 208c) as described above in reference to FIGS. 2B-2D, so that each bond pad is connected to a plurality of electrodes. In this way, a uniform period distribution of electrodes may create a uniform field for carriers to move efficiently. Any suitable number of first electrodes 301 and second electrodes 302 may be used (one or more first electrodes 301 and/or one or more second electrodes 302) and can be formed in any uniform or non-uniform distribution. In FIG. 2D, the bond pads are electrically connected to the electrodes also through vias 272 in a semiconductor layer 270 and electrode contacts 214c and 216c.

In some embodiments, the first electrode 311 and the second electrode 312 are interdigitated electrodes. The first electrode 311 may be biased with an opposite bias of the second electrode 312. The first electrode 311 may be biased with a positive bias, and the second electrode may be biased with a negative bias.

In some embodiments, one or more first electrodes 321 and one or more second electrodes 322 are in a shape of concentric rings. The first electrode 321 may be biased with an opposite bias of the second electrodes 322. The first electrode 321 may be biased with a positive bias, and the second electrode 322 may be biased with a negative bias.

In FIG. 3A, one first electrode 321 and two second electrodes 322 are shown. In some embodiments, the first electrode 321 is electrically connected to the first bond pad (e.g., bond pad 204c or 204d) and the two second electrodes 322 are electrically connected to the second bond pad (e.g., bond pad 206c or 206d) as described in relation to FIGS. 2B-2D. However, any suitable number of first electrodes 321 and second electrodes 322 may be used (one or more first electrodes 321 and/or one or more second electrodes 322) and can be formed in any uniform or non-uniform distribution.

FIG. 3B is a sectional side view of a stacked quantum dot sensor, in accordance with embodiments of the present disclosure. FIG. 3A shows quantum dot substrates 341, 342 and 343. In some embodiments, quantum dot substrates 341, 342, and 343 may be similar to quantum dot substrates 118c, 128c, and 138c of FIG. 1B, except that the quantum dot substrates 341, 342, and 343 each include quantum dots that are patterned within a sensor pixel that do not overlap in a vertical manner. In this way, an active area of a quantum dot substrate 341, 342, and 343 may be smaller than an active area of a quantum dot substrate 118a, 128a, and 138a of FIG. 1B. Although not shown in FIG. 3A, each quantum dot substrate may include features similar to those described in relation to FIG. 1B. For example, each quantum dot substrate may comprise corresponding bond pads, electrodes, through vias, and an interconnect layer comprising interconnects in an insulating material. The interconnects may connect electrodes to bond pads or through vias to bond pads.

In some embodiments, the quantum dot substrates 341, 342, and 343 comprise a patterned matrix, the matrix comprising quantum dots in a transparent conductive material. In some embodiments, the transparent conductive material may be embedded in a non-conductive transparent dielectric layer in each film. In some embodiments, the quantum dot substrates 341, 342, and 343 comprise a patterned matrix, the matrix comprising quantum dots in transparent non-conductive material, and the electrodes may comprise transparent conductive structures that protrude in the patterned matrix.

FIG. 3C is an illustrative schematic sectional side view of quantum dots deposited in an opening 350 of a substrate that is shaped to enhance light collection, in accordance with embodiments of the present disclosure. The opening 350 is shaped a way to enhance light collection, as shown by the example light ray depicted. The opening 350 may be coated with a reflective material. The example light ray is shown to reflect off a side of the opening 350 to be directed towards the quantum dots in the opening 350. For example, patterned conductive matrices may be formed in an opening 350 in a substrate to enhance light collection.

In some embodiments, the films of FIGS. 1A-1B may have sensors with such a shape to enhance light collection. In some embodiments, patterned conductive matrices may be formed in an opening 350 in a substrate to enhance light collection. For example, a second dielectric layer may be formed on a substrate comprising electrodes (e.g., electrodes 141, 143, and 145) in a first dielectric layer (e.g., dielectric layer 113, 123, or 133 of FIG. 1B). The second dielectric layer may be etched in a manner to create openings in a shape of the cross section as shown in FIG. 3C and expose surfaces of electrodes (e.g., electrodes 141, 143, and 145), and a conductive matrix may be deposited in the openings formed in the second dielectric layer. In some embodiments, a dielectric layer or sealing layer may be deposited on the conductive matrix and the second dielectric layer. As another example, a dielectric layer may be formed on an interconnect layer (e.g., interconnect layer 408 in FIG. 4B), etched in a manner to create openings in a shape of the cross section as shown in FIG. 3C and to expose electrodes 414 and 416, and a conductive matrix may be deposited in the openings formed in the dielectric layer. In some embodiments, a dielectric layer or sealing layer may be deposited on the conductive matrix and the dielectric layer. In some embodiments, a matrix or semiconductive matrix may be used in place of the conductive matrix.

As an example, in some embodiments, a dielectric layer may be formed on electrodes in a dielectric layer as described in relation to FIGS. 1A-1B. The dielectric layer may be etched in a manner to create openings in a shape of the cross section as shown in FIG. 3B and to expose surfaces of the electrodes. In some embodiments, a conductive matrix (e.g., conductive matrix 218c) may be deposited in the openings formed in the dielectric layer. In some embodiments, a dielectric layer or sealing layer may be deposited on the conductive matrix (e.g., conductive matrix 218c) and the dielectric layer. In some embodiments, a semiconductive matrix or a matrix (e.g., matrix 518) may be used in place of the conductive matrix (e.g., conductive matrix 218c). In some embodiments, a mirror coating or reflective coating may be deposited on the inner sidewalls of an opening 350 to reflect light towards the quantum dots. In some embodiments, a matrix or semiconductive matrix may be used in place of the conductive matrix.

As another example, a dielectric layer may be formed on an interconnect layer (e.g., interconnect layer 208b) as described in relation to FIG. 2C, etched in a manner to create openings in a shape of the cross section as shown in FIG. 3B and to expose electrodes (e.g., electrodes 214b and 216b), and a conductive matrix (e.g., conductive matrix 218c) may be deposited in the openings formed in the dielectric layer. In some embodiments, a dielectric layer or sealing layer may be deposited on the conductive matrix (e.g., conductive matrix 218c) and the dielectric layer. In some embodiments, a semiconductive matrix or a matrix (e.g., matrix 518) may be used in place of the conductive matrix (e.g., conductive matrix 218c).

In another example, a dielectric layer may be formed on a semiconductor layer (e.g., semiconductor layer 270) as described in FIG. 2D, etched in a manner to create openings in a shape of the cross section as shown in FIG. 3B and to expose electrodes as described above in relation to FIG. 2D, and a conductive matrix (e.g., conductive matrix 218d) may be deposited in the openings formed in the dielectric layer. In some embodiments, a dielectric layer or sealing layer may be deposited on the conductive matrix (e.g., conductive matrix 218d) and the dielectric layer. In some embodiments, a semiconductive matrix or a matrix (e.g., matrix 518) may be used in place of the conductive matrix (e.g., conductive matrix 218d).

In some embodiments, an electron transport layer (e.g., TiOx, ZnO) or a hole transport layer (e.g., p-type polymer) may be deposited between respective electrodes and a matrix to improve carrier transport and injection. For example, in an image sensor with a matrix a top electrode (e.g., similar to FIG. 2B except conductive matrix 218b is replaced with matrix 518), a hole transport layer may be deposited between a transparent top electrode (e.g., transparent conductive layer 219) and the matrix 518 and an electron transport layer may be deposited between electrode 214a and the matrix 518. In some embodiments, a graphene sheet or layer may be formed between the electrodes and the matrix to improve carrier transport. For example, a graphene sheet may be formed between the electrodes (e.g., electrodes 504 and 506) the matrix (e.g., matrix 518).

FIG. 4A schematically illustrates a hybrid bonding method for forming an image sensor device, in accordance with embodiments of the present disclosure. For example, an image sensor device is formed by direct or hybrid bonding of a sensor (e.g., stacked sensor of FIG. 1A) to an image processor device 402. The image processor device 402 comprises bond pads (e.g., conductive features 434 and 436) embedded in a dielectric layer 432 on a substrate. The method includes aligning the bond pads (e.g., conductive features 104a and 106a) of the sensor with the bond pads of the image processor device 402 and contacting the sensor and the image processor device 402 at ambient temperature. Here, contacting the sensor and image processor device 402 forms a workpiece where the sensor and the image processor device 402 are attached to one another through direct bonds formed between the dielectric layers 112 and 432 without the use of an intervening adhesive. The method includes heating the workpiece to a processing temperature between about 50° C. to about 150° C. or more, or of about 150° C. or more, such as about 250° C. or more, or about 300° C. or more, or to a temperature less than about 300° C., or less than about 250° C., to form direct interconnects 454a and 456a via hybrid bonding of the bond pads (e.g., conductive features 104a and 106a) of the sensor to bond pads (e.g., conductive features 434 and 436) of the image processor device 402. For example, hybrid bonding may comprise directly bonding the bond pads of the sensor to the bond pads of the image processor device 402. FIG. 4A shows an example of a sensor with two sensor pixels (e.g., sensors, photodiodes). However, any number of sensor pixels may be used (e.g., one, two or more, e.g., thousands, or millions).

In some embodiments, the dielectric layers 112 and 432 may comprise materials used for bonding layer 808a and 808b, and the bond pads of the sensor and the bond pads of the image processor device may comprise materials used for the conductive features 806a and 806b. In some embodiments, the sensor and/or the image processor device 402 may comprise dummy substrates, passive interposers, passive optical elements (e.g., glass substrates, gratings, lenses), or materials used for base substrate portions 810a, 810b as described in reference to FIGS. 8A-B.

FIG. 4B schematically illustrates a hybrid bonding method for forming an image sensor device, in accordance with embodiments of the present disclosure. For example, an image sensor device is formed by direct or hybrid bonding of a sensor 401 to an image processor device 402. In some embodiments, the sensor 401 corresponds to (e.g., is the same as or similar to) sensor 201b in FIG. 2B. In some embodiments, there may be multiple quantum dot layers and at least one of the quantum dot layers includes a sensor similar to sensor 401. For example, a first quantum dot layer 118b, second quantum dot layer 128b, and/or third quantum dot layer 138b of FIG. 1A may comprise a sensor similar to sensor 401. A first, second, and third quantum dot layer 118c, 128c, and 138c of FIG. 1B may each comprise a sensor similar to sensor 401. The method includes aligning the bond pads (e.g., conductive features 404 and 406) of the sensor 401 with the bond pads (e.g., conductive features 434 and 436) of the image processor device 402 and contacting the sensor 401 and the image processor device 402 at ambient temperature. Here, contacting the sensor 401 and image processor device 402 forms a workpiece where the sensor and the image processor device 402 are attached to one another through direct bonds formed between insulating material of an interconnect layer 408 (e.g., dielectric layers) and dielectric layer 432 without the use of an intervening adhesive. The method includes heating the workpiece to a processing temperature of between about 50° C. to about 150° C. or more, or of about 150° C. or more, such as about 250° C. or more, or about 300° C. or more, or to a temperature less than about 300° C., or less than about 250° C., to form direct interconnects (e.g., interconnect 454b and interconnect 456b) via hybrid bonding of the bond pads (e.g., conductive features 404 and 406) of the sensor 401 to bond pads (e.g., conductive features 434 and 436) of the image processor device 402. For example, hybrid bonding may comprise directly bonding the bond pads of the sensor to the bond pads of the image processor device 402. FIG. 4B shows an example of a sensor 401 with two sensor pixels (e.g., sensors, photodiodes). However, any number of sensor pixels may be used (e.g., one, two or more, e.g., thousands, or millions).

The sensor 401 comprises a top electrode 419 and a conductive matrix 418. The top electrode 419 may comprise a transparent conductive material. The conductive matrix 418 comprises quantum dots 417 in a transparent conductive material 415. The conductive matrix 418 is patterned.

A dielectric layer 420 may cover the transparent electrode (e.g., top electrode 419). The dielectric layer 420 may serve as a barrier or encapsulation layer to protect the quantum dots from oxidation. The dielectric layer 420 may comprise an oxide material. The dielectric layer 420 may comprise a material transparent to wavelengths to be detected by the sensor (e.g., infrared (IR), near IR (NIR), short wave IR (SWIR), visible, or any suitable wavelength range). For example, if the sensor is configured to detect short wave infrared (SWIR) wavelengths, the dielectric layer 420 may be transparent to wavelengths of the SWIR range. If the sensor 401 is configured to detect a visible range, the second dielectric layer 420 may be transparent to wavelengths in the visible range.

In some embodiments, the sensor comprises an interconnect layer 408 on a substrate with bond pads (e.g., conductive features 404 and 406) to be bonded to bond pads (e.g., conductive features 434 and 436) of an image processor device 402. For example, electrodes 414 and 416 (and top electrode 419) of the sensor may be electrically connected to bond pads (e.g., conductive features 404 and 406) via interconnects 409 in in the interconnect layer 408.

In some embodiments, the electrodes or bond pads of the sensor 401 are directly bonded to bond pads of a processor device.

In some embodiments, each quantum dot substrate may comprise quantum dots and conductive particles in a transparent conductive material. In some embodiments, each quantum dot substrate may comprise quantum dots and conductive nanoparticles in a transparent insulating material. In some embodiments, each quantum dot substrate may comprise a quantum dot layer on conductive structures. In some embodiments, each quantum dot substrate may comprise a quantum dot layer on conductive porous structures. A quantum dot substrate of any embodiment mentioned in this disclosure may be stacked together. For example, upper quantum dot substrates (e.g., quantum dot substrates 138c and 128c) with transparent components (e.g., bond pads, vias) films may be stacked in a configuration of FIG. 1B. A lower quantum dot substrate (e.g., quantum dot substrate 118c) may include non-transparent components (e.g., bond pads, electrodes comprising metal material). In some embodiments, quantum dot substrates with non-transparent or opaque components (e.g., interconnects, bond pads, conductive structures, conductive porous structures) may be stacked using a configuration of FIG. 3B.

In some embodiments, the hybrid bonding method of an image sensor and an image processor device as described in relation to FIGS. 4A and 4B may be applied to image sensors described in embodiments of this disclosure. For example, the stacked image sensor in FIG. 4A may be applied to any suitable image sensor embodiment described in this disclosure. Although the image sensor in FIG. 4B shows a single layer, the image sensor may be stacked multiple layers.

FIG. 5 is an illustrative schematic sectional side view of an image sensor 501 with conductive particles 515, in accordance with embodiments of the present disclosure. The image sensor 501 comprises a matrix 518 with conductive particles 515 on electrodes 504 and 506 in a dielectric layer 512. A substrate 510 comprises the electrodes 504 and 506 embedded in the dielectric layer 512. The matrix 518 comprises conductive particles 515, quantum dots 517, and a transparent material layer 516. In some embodiments, a dielectric layer or sealing layer may be deposited on the matrix 518. The image sensor 501 comprises a plurality of sensors (e.g., photodiodes, two or more photodiodes, e.g., thousands of photodiodes, or millions of photodiodes) although one sensor is shown in FIG. 5.

In some embodiments, a method of forming the image sensor 501 comprises forming the matrix 518, and before or after forming the matrix 518, forming the electrodes 504 and 506. In some embodiments, forming the matrix 518 may comprise forming a matrix comprising conductive particles 515 and quantum dots 517 embedded in a transparent material layer 516. In some embodiments, the transparent material layer 516 is a transparent conductive material layer, a transparent insulating material layer, or a transparent semiconductive material layer.

In some embodiments, the transparent material layer 516 is substantially similar to the transparent conductive material layer described above in relation to FIGS. 1A-1B. For example, the matrix 518 may be a conductive matrix similar to the conductive matrix described above in relation to FIGS. 1A-1B, except it further comprises conductive particles 515. The matrix 518 may comprise quantum dots 517 and conductive particles 515 embedded in a transparent conductive material layer (e.g., transparent conductive material layer 141) as described above in relation to FIGS. 2A-2B. The conductive particles 515 may transfer the photogenerated charges to the conductive matrix, other conductive particles 515, or quantum dots 517.

In some embodiments, forming the matrix 518 comprises depositing transparent material, conductive particles 515, and quantum dots 517 from a suspension of transparent material (e.g., transparent conductive material, transparent semiconductive material, or transparent non-conductive material), conductive particles 515, and quantum dots 517. The suspension may be deposited via spin coating, printing, or spray coating. The matrix 518 may be patterned. The image sensor 501 may comprise a repeating pattern of matrices (shown as a single patterned matrix 518) and corresponding electrodes 504 and 506. The matrix may be formed patterned (e.g., printed). The matrix 518 may be formed as a continuous layer and the continuous layer may be patterned. For example, the matrix 518 may be patterned using photolithography.

In some embodiments, the transparent material layer 516 is a transparent insulating material layer. The transparent material layer 516 may be a transparent encapsulant. For example, the transparent insulating material may be a polymer. The matrix 518 may comprise quantum dots 517 and conductive particles 515 embedded in a transparent insulating material layer. The conductive particles 515 may transfer the photogenerated charges to other conductive particles 515 or quantum dots 517. The conductive particles 515 may assist in carry the photogenerated charges to the electrodes 504 and 506.

In some embodiments, conductive particles 515 (e.g., comprising ITO material) and quantum dots 517 may be added to a polymer, dispersed using sonication, and/or distributed via spin-coating. For example, conductive particles 515 and quantum dots 517 may dispersed in a polymer using sonication, and spin coated on a substrate 510. In some embodiments, the spun coated film of conductive particles 515 and quantum dots 517 may be patterned. In some embodiment, the conductive particles 515 and quantum dots 517 may be printed.

The conductive particles 515 may comprise any suitable conductive material (e.g., metal, transparent conductive oxide). For example, the conductive material may comprise indium tin oxide, graphite, copper, aluminum, gold, silver, platinum, palladium, or some combination thereof. The conductive particles 515 may be transparent. In some embodiments, the conductive particles 515 comprise a reflective surface.

The conductive particles 515 may be substantially smaller in size compared to quantum dots 517. For example, a ratio of a mean diameter of the quantum dots 517 to a mean diameter of the conductive particles 515 may be greater than about 100, than about 50 or than about 10.

FIG. 6 is an illustrative schematic sectional side view of an image sensor 601 with conductive structures 611 (e.g., conductive nano-structures), in accordance with embodiments of the present disclosure. The image sensor 601 comprises conductive structures 611, a quantum dot layer 618, and electrodes 604 and 606. The quantum dot layer 618 comprises quantum dots 617 in a transparent insulating material 616. The transparent insulating material 616 may be a transparent encapsulant. In some embodiments, the quantum dot layer 618 comprises quantum dots 617. In some embodiments, a dielectric layer or sealing layer may be deposited on the quantum dot layer 618. The image sensor 601 comprises a plurality of sensors (e.g., photodiodes, two or more photodiodes, e.g., thousands of photodiodes, or millions of photodiodes) although one sensor is shown in FIG. 6.

In some embodiments, a method of forming the image sensor 601 comprises forming the conductive structures 611 on a surface of a substrate 610 and forming a quantum dot layer 618 over the conductive structures 611. The conductive structures 611 may extend upwardly from the substrate surface and may be electrically coupled to electrodes 604 and 606 disposed in the substrate 610. Respective portions of the quantum dot layer 618 may be disposed between adjacent conductive structures 611.

In some embodiments, forming the conductive structures 611 comprise growing the conductive structures from a surface of the substrate 610. The conductive structures 611 may grow from a surface of the electrodes 604 and 606. The electrodes 604 and 606 are disposed in electrical communication with conductive structures 611.

The conductive structures 611 may grow from a surface of the dielectric layer 612. In some embodiments, the conductive structures 611 extend from the electrodes 604 and 606 and do not extend from the dielectric layer 612. The electrodes 604 and 606 may be bond pads.

The conductive structures 611 may comprise wires, nanowires, carbon nano tubes, conductive pillars, conductive nanopillars, conductive posts, or some combination thereof extending from a surface of the electrodes 604 and 606. For example, a nanowire array may be grown from a surface of the substrate 610. The diameter of nanowires or nanopillars may be a few nanometers.

In some embodiments, forming the quantum dot layer 618 comprises depositing a suspension comprising quantum dots 617 on the conductive structures 611. In some embodiments, the suspension comprises quantum dots 617 and transparent insulating material 616 (e.g., a polymer, encapsulant). In some embodiments, the suspension comprises quantum dots 617, and the quantum dot layer 618 may comprise quantum dots 617.

In some embodiments, the image sensor 601 comprises a repeating pattern of quantum dot layers 618, conductive structures 611, and corresponding electrodes 604 and 606. In some embodiments, the quantum dot layer 618 may be formed patterned via inkjet printing. In some embodiments, the quantum dot layer 618 may be deposited as a continuous layer (e.g., spin coating, spray coating) and then patterned (e.g., via photolithography).

FIG. 7 is an illustrative schematic sectional side view of an image sensor 701 with porous conductive structures 721, in accordance with embodiments of the present disclosure. The image sensor 701 comprises porous conductive structures 721, a quantum dot layer 718, and electrodes 704 and 706. A substrate 710 may comprise the electrodes 704 and 706 embedded in a dielectric layer 712. The quantum dot layer 718 may comprise quantum dots 717 in a transparent insulating material layer 716 (e.g., polymer, encapsulant). In some embodiments, the quantum dot layer 718 comprises quantum dots 717. In some embodiments, a dielectric layer or sealing layer may be deposited on the quantum dot layer 718. The image sensor 701 comprises a plurality of sensors (e.g., photodiodes, two or more photodiodes, e.g., thousands of photodiodes, or millions of photodiodes) although one sensor is shown in FIG. 7.

In some embodiments, a method of forming the image sensor 701 comprises forming the electrodes 704 and 706, forming the porous conductive structures 721, and forming the quantum dot layer 718. In some embodiments, forming a porous conductive structure 721 comprises forming a conductive layer and growing conductive structures from the conductive layer. In some embodiments, forming the porous conductive structure 721 comprises forming a conductive layer and etching openings in the conductive layer. The openings may be partially etched in the conductive layer so that a continuous portion of the conductive layer remains in the porous conductive structure 721.

The porous conductive structures 721 may be transparent or opaque. Each porous conductive structure 721 may comprise a conductive layer (e.g., plate, continuous layer of conductive material) with pillars formed on the conductive layer. The conductive layer and/or pillars may be formed of a conductive material. The conductive material may be a transparent conductive material (e.g., transparent conductive oxide). The conductive material may be an opaque conductive material (e.g., metal). The conductive material may be an alloy of copper nanoparticles, nanocopper, CNT, and/or copper. The conductive material may comprise nanoparticles in a copper alloy. Nanoparticles may improve conductivity within a copper alloy. The conductive material may comprise CNT incorporated in a transparent conductive material to improve the conductivity of the transparent conductive material.

The electrodes 704 and 706 are disposed within a dielectric layer 712. The electrodes 704 and 706 may be bond pads. The porous conductive structures 721 are electrically coupled to the electrodes 704 and 706. For example, first and second porous conductive structures 721 are electrically coupled to electrodes 704 and 706, respectively.

In some embodiments, forming the quantum dot layer 718 comprises depositing a suspension comprising quantum dots 717 and transparent insulating material (e.g., a polymer, encapsulant) on the porous conductive structures 721. In some embodiments, the suspension comprises quantum dots 717, and the quantum dot layer 718 may comprise quantum dots 717.

In some embodiments, the image sensor 701 comprises a repeating pattern of quantum dot layers 718, porous conductive structures 721, and corresponding electrodes 704 and 706. In some embodiments, the quantum dot layer 718 may be formed patterned via inkjet printing. In some embodiments, the quantum dot layer 718 may be deposited as a continuous layer (e.g., spin coating, spray coating) and then patterned (e.g., via photolithography).

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 1B, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO₃) or lithium niobate (LiNbO₃), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D₂W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 1A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 811 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

Certain implementations disclosed herein relate to optoelectronic devices that include directly bonded contacts comprising optically transparent or optically semi-transparent electrically conducting material (referred to herein collectively as transparent conductors or TCs) instead of metal direct bonded contacts. For example, the optoelectronic devices can include optical elements or devices (e.g., photodiodes) that are stacked on or bonded to one another to form a bonded structure. The TCs on separate substrates can be planarized and the planarized surfaces of the substrates can be placed in contact with one another, as described herein, to form the bonded structures.

In certain implementations, the optoelectronic devices described herein are configured to be used in various contexts which are area-limited or other designs comprising an optoelectronic (e.g., electro-optical) element within a stack of other optical elements, beneficially utilizing the TCs for providing electrical connection between electrical elements while not appreciably blocking light.

As used herein, the term “optically transparent” includes but is not limited to optically translucent, optically semi-transparent, and/or having an optical transmittance of at least 50% (e.g., at least 60%; at least 75%; at least 88%; greater than or equal to 95%) at optical wavelengths in a predetermined range. For example, the predetermined range for optically transparent components (e.g., elements; substrates; layers; devices; features) can be visible wavelengths (e.g., 390 nanometers to 750 nanometers; 400 nanometers to 700 nanometers), ultraviolet wavelengths (e.g., 100 nanometers to 400 nanometers), infrared wavelengths (e.g., 800 nanometers to 1 millimeter), and/or short-wave infrared (SWIR) wavelengths (e.g., 1400 nanometers to 3000 nanometers).

In some embodiments, some electrically conductive oxides (e.g., indium tin oxide or ITO) or nitrides may have the ability to self-bond at modest temperatures (e.g., in a range of 75° C. to 400° C.; in a range of 120° C. to 300° C.; in a range of 150° C. to 300° C.). In certain implementations, use of electrically conductive oxide or nitride layers can simplify processes for bonding (e.g., blanket wafer and hybrid bonding surfaces) by omitting one or more other processing steps (e.g., planarization and/or surface activation). For example, the electrically conductive oxide or nitride layers can be self-leveled if planarized before patterning. In conjunction with certain layout structures, such electrically conductive oxide or nitride layers can be used to bond multiple input/output components with a single material interface. For example, ITO can be used to bond two substrates without a surface activation step, and in certain implementations, without a surface planarization (e.g., chemical-mechanical polishing or CMP) step. The electrically conductive oxide or nitride layers can also allow bonding at modest temperatures (e.g., less than 300° C.) and can be used for surface mounting. In view of the electrical conductivity, such layers can provide electromagnetic shielding for other components of the electronic packages. In addition, because certain such materials are substantially optically transparent, they can be used for bonding optoelectronic applications, as well as in other structures where photon transmission is not a factor.

In embodiments where the substrates are bonded using hybrid dielectric and metal bonds, the method may further include planarizing or recessing the metal features below the field surface before contacting and bonding the dielectric material layers. After the dielectric bonds are formed, the substrates may be heated to a temperature of 150° C. or more and maintained at the elevated temperature for a duration of about 1 hour or more, such as between 8 and 24 hours, to form direct metallurgical bonds between the metal features. Suitable direct dielectric and hybrid bonding technologies that may be used to perform aspects of the methods described herein include ZiBond® and DBI®, each of which are commercially available from Adeia, San Jose, CA, USA.

It is contemplated that any combination of the methods described above may be used to form the sensor whether or not expressly recited herein.

The embodiments discussed above are intended to be illustrative and not limiting. One skilled in the art would appreciate that individual aspects of the quantum dot sensor, image sensor device, and methods discussed herein may be omitted, modified, combined, and/or rearranged without departing from the scope of the claimed subject matter.

1. A method of forming a stacked image sensor comprising:
providing a first substrate comprising:
a first matrix comprising first quantum dots;
a first dielectric layer adjacent to the first matrix; and
first bond pads disposed in the first dielectric layer;
providing a second substrate comprising:
a second matrix comprising second quantum dots;
a second dielectric layer adjacent to the second matrix;
second bond pads disposed in the second dielectric layer; and
hybrid bonding the first substrate to the second substrate without use of an intervening adhesive to form the stacked image sensor, wherein the hybrid bonding connects the first bond pads to the second bond pads.

2. The method of claim 1, wherein:
the first matrix is a first conductive matrix comprising the first quantum dots disposed in a first transparent conductive material; and
the second matrix is a second conductive matrix comprising the second quantum dots disposed in a second transparent conductive material.

3. The method of claim 1, further comprising:
subsequent to hybrid bonding the first substrate and the second substrate, forming pixel stacks of the stacked image sensor by removing portions of the first matrix and portions of the second matrix.

4. The method of claim 1, wherein:
providing the first substrate comprises patterning first electrodes, wherein the first matrix is in electrical communication to the first electrodes; and
providing the second substrate comprises patterning second electrodes, wherein the second matrix is in electrical communication with the second electrodes.

5. The method of claim 4, wherein:
the first electrodes comprise a rectangular array of first electrodes, interdigitated first electrodes, or alternating concentric rings of first electrodes when viewed from top down or bottom up; and
the second electrodes comprise a rectangular array of second electrodes, interdigitated second electrodes, or alternating concentric rings of second electrodes when viewed from top down or bottom up.

6. The method of claim 1, wherein:
providing the first substrate comprises patterning the first matrix; and
providing the second substrate comprises patterning the second matrix.

7. The method of claim 6, further comprising:
prior to hybrid bonding, aligning the first substrate and the second substrate to offset the patterned first matrix and the patterned second matrix when viewed from top down or bottom up.

8. The method of claim 6, wherein:
providing the first substrate comprises, prior to forming the first matrix, forming a first reflective layer, wherein the first reflective layer is shaped to direct incident light towards the first matrix of the first substrate; and
providing the second substrate comprises, prior to forming the second matrix, forming a second reflective layer, wherein the second reflective layer is shaped to direct incident light toward the second matrix of the second substrate.

9. The method of claim 1, wherein:
providing the first substrate comprises:
forming the first matrix on a bottom first electrode of the first electrodes; and
forming a top first electrode of the first electrodes on the first matrix, wherein the top first electrode comprises a transparent conductive oxide.

10. The method of claim 9, wherein the transparent conductive oxide comprises indium tin oxide, zinc oxide, tin oxide, aluminum doped zinc oxide, indium oxide, cadmium oxide, or some combination thereof.

11. (canceled)

12. A stacked image sensor comprising:
a first substrate comprising:
a first matrix comprising first quantum dots;
a first dielectric layer adjacent to the first matrix; and
first bond pads disposed in the first dielectric layer; and
a second substrate comprising:
a second matrix comprising second quantum dots;
a second dielectric layer adjacent to the second matrix; and
second bond pads disposed in the second dielectric layer, wherein the first substrate is hybrid bonded to the second substrate without use of an intervening adhesive to form the stacked image sensor to connect the first bond pads to the second bond pads.

13. The stacked image sensor of claim 12, wherein:
the first matrix is a first conductive matrix comprising the first quantum dots disposed in a first transparent conductive material; and
the second matrix is a second conductive matrix comprising the second quantum dots disposed in a second transparent conductive material.

14. The stacked image sensor of claim 11, further comprising:
a repeating pattern of first matrices and corresponding first electrodes; and
a repeating pattern of second matrices and corresponding second electrodes.

15. The stacked image sensor of claim 11, further comprising:
first electrodes of the first substrate, wherein the first matrix is in electrical communication to the first electrodes; and
second electrodes of the second substrate, wherein the second matrix is in electrical communication with the second electrodes.

16. The stacked image sensor of claim 15, wherein:
the first electrodes comprise a rectangular array of first electrodes, interdigitated first electrodes, or alternating concentric rings of first electrodes when viewed from top down or bottom up; and
the second electrodes comprise a rectangular array of second electrodes, interdigitated second electrodes, or alternating concentric rings of second electrodes when viewed from top down or bottom up.

17. The stacked image sensor of claim 11, further comprising:
a third dielectric layer of the first substrate, wherein portions of the third dielectric is laterally adjacent to a patterned first matrix; and
a fourth dielectric layer of the second substrate, wherein portions of the fourth dielectric layer is laterally adjacent to a patterned second matrix.

18. The stacked image sensor of claim 17, wherein the patterned first matrix is offset from the patterned second matrix when viewed from top down or bottom up.

19. The stacked image sensor of claim 17, further comprising:
a first reflective layer of the first substrate, wherein the first reflective layer is shaped to direct incident light towards the first matrix of the first substrate; and
a second reflective layer of the second substrate, wherein the second reflective layer is shaped to direct incident light toward the second matrix of the second substrate.

20. The stacked image sensor of claim 12, further comprising:
a bottom first electrode, wherein the first matrix is formed on the bottom first electrode; and
a top first electrode on the first matrix, wherein the top first electrode comprises a transparent conductive oxide.

21. The stacked image sensor of claim 20, wherein the transparent conductive oxide comprises indium tin oxide, zinc oxide, tin oxide, aluminum doped zinc oxide, indium oxide, cadmium oxide, or some combination thereof.

22. (canceled)
